(19) United States
(12) Patent Application Publication
(10) Pub. No.: US 2016/0163987 A1
(43) Pub. Date: Jun. 9, 2016

(54) ELECTRO-OPTICAL DEVICE AND THE USE THEREOF

(71) Applicant: MERCK PATENT GMBH, Darmstadt (DE)

(72) Inventors: Susanne Heun, Bad Soden (DE); Aurelie Ludemann, Frankfurt Am Main (DE); Junyou Pan, Frankfurt Am Main (DE); Niels Schulte, Kelkheim (DE)

(73) Assignee: Merck Patent GmbH, Darmstadt (DE)

(21) Appl. No.: 14/908,335

(22) PCT Filed: Jun. 26, 2014
(86) PCT No.: PCT/EP2014/001738

§ 371 Date: Jan. 28, 2016

(30) Foreign Application Priority Data
Jul. 29, 2013 (EP) 13003770.8

(51) Int. Cl. H01L 51/00; C09K 11/06

(52) U.S. Cl. CPC H01L 51/0036; H01L 51/0039; H01L 51/0043; H01L 51/0037; H01L 51/0085; H01L 51/0035; C09K 11/06; H01L 51/5004

(57) ABSTRACT

The present invention relates to an electro-optical device containing a) an anode, b) a cathode and c) at least one first emitter layer arranged between anode and cathode, containing at least one semiconducting, organic material, said device being characterized in that at least one second emitter layer comprising at least one polymer having hole-conducting properties and at least one emitter is arranged between the first emitter layer and the anode, and to the use thereof. The use of two emitter layers allows simple production from solution, and the production of electroluminescence devices having broadband emission.

The present invention relates to a novel design principle for organic electrooptical devices, especially for electroluminescent elements, and to the use thereof in displays and lighting means based thereon.

In a number of different kinds of applications which can be attributed to the electronics industry in the broadest sense, the use of organic semiconductors as functional materials has been reality for some time or is expected in the near future.

For instance, light-sensitive organic materials (e.g. phthalocyanines) and organic charge transport materials (e.g. triarylamine-based hole transport materials) have already been used for several years in photocopiers.

Some specific semiconductive organic compounds, some of which are also capable of emitting light in the visible spectral region, are now already being used in commercially available devices, for example in organic electroluminescent devices.

The individual components thereof, organic light-emitting diodes (OLEDs), have a very broad spectrum of application. OLEDs are already finding use, for example, as:
white or colored backlighting for monochrome or multicolor display elements (for example in pocket calculators, mobile phones and other portable applications),
large-area displays (for example as traffic signs or posters),
lighting elements in a wide variety of different colors and forms,
monochrome or full-color passive matrix displays for portable applications (for example for mobile phones, PDAs and camcorders),
full-color large-area and high-resolution active matrix displays for a wide variety of different applications (for example for mobile phones, PDAs, laptops and televisions).

Development in some of these applications is already very advanced. There is nevertheless still a great need for technical improvements.

There is currently intensive study of conjugated polymers as promising materials for polymeric OLEDs, called PLEDs. The ease of processing thereof, in contrast to vapor-deposited arrangements made from small molecules, called small molecule devices (“SMOLEDs”), promises less expensive production of organic light-emitting diodes. The use of interlayers in a layer structure, as described, for example, in WO 04/084260 A, has distinctly increased the lifetime and efficiency of PLEDs. These interlayers are applied between anode and the layer of light-emitting polymers. Their function is to facilitate, or to actually make possible, the injection and transport of holes, i.e. of positive charge carriers, into the light-emitting polymer, and to block electrons at the interface between interlayer and layer of light-emitting polymer. These interlayers consist of polymers having a high proportion of hole-transporting units joined via a conjugated backbone. In addition, these polymers simultaneously block the transport of electrons.

The structure of multilayer PLEDs by application of layers from solution is subject to the general problem that, in the course of application, the layers beneath are partly or even fully dissolved again. Typically, it is therefore necessary to take additional measures in order to prevent partial redissolution of the layers. A commonly used measure is the crosslinking of the polymer in the layer applied. This is costly and inconvenient and entails additional working steps. There has therefore already been a search for ways of avoiding the crosslinking of the polymer layers applied. A measure already put into practice is the application of interlayers. This method functions particularly in combination with blue light-emitting PLEDs. The interlayer is applied here by inkjet printing or by spin-coating. The thickness of this layer is adjusted such that the layer is not completely dissolved again in the subsequent working step.

In known PLEDs having interlayers, the emitted radiation comes exclusively from the emitter layer. The possibility of applying two polymer layers without conducting a crosslinking reaction has not yet been utilized to date in order to incorporate a plurality of emitters into the PLED.

It has now been found that, surprisingly, electrooptical devices having a plurality of emitters can be produced in a simple manner and without conducting a crosslinking step when emitters are also used in the interlayer in addition to the emitter layer. This allows the simple production of multicolor OLEDs in which at least two different emitter layers can be processed from solution.

Proceeding from this prior art, it was an object of the present invention to provide an electrooptical device producible by simple application methods from solution, and having a plurality of emitters and a longer lifetime compared to known devices.

The present invention thus provides an electrooptical device comprising
a) an anode,
b) a cathode, and
c) at least one first emitter layer disposed between anode and cathode, comprising at least one semiconductive organic material,
   characterized in that at least one second emitter layer disposed between the first emitter layer and the anode includes at least one polymer having hole-conducting properties and at least one emitter.

The devices of the invention are characterized by the use of selected polymeric materials in the second emitter layer (=interlayer) which comprises one or more emitters above it.

In a preferred embodiment, the emitters of the second emitter layer or of the interlayer are selected such that they have a lowest unoccupied molecular orbital (“LUMO”) higher than the LUMO of the semiconductive organic material of the first emitter layer. The LUMO of the emitter of the interlayer is preferably 0.1 eV and more preferably 0.2 eV higher than the LUMO of the first emitter layer.

Of the various energy levels that the chemical compounds have, the HOMO (“Highest Occupied Molecular Orbital”) and the LUMO (“Lowest Unoccupied Molecular Orbital”) in particular play a major role.

These energy levels can be determined by photoemission, e.g. XPS (“X-ray Photoelectron Spectroscopy”) and UPS (“Ultraviolet Photoelectron Spectroscopy”), or by cyclic voltammetry (“CV”) for the oxidation and reduction.

For some time, it has also been possible to determine the energy levels of the molecular orbitals, especially of the occupied molecular orbitals, via quantum-chemical calculation methods, for example by means of Density Functional Theory (“DFT”). A detailed description of such quantum-chemical calculations can be found in WO 2012/171609.

In principle, it is possible to use any emitter known to those skilled in the art as emitter in the emitter layer of the device of the invention.

In a preferred embodiment, the emitter is integrated into a polymer as a repeat unit.

In a further preferred embodiment, the emitter is mixed into a matrix material which may be a small molecule, a polymer, an oligomer, a dendrimer or a mixture thereof.

Preference is given to an emitter layer comprising at least one emitter selected from fluorescent compounds, phosphorescent compounds and emitting organometallic complexes.

The expression “emitter unit” or “emitter” refers in the present application to a unit or compound where radiative decay with emission of light occurs on acceptance of an exciton or formation of an exciton.

There are two emitter classes: fluorescent and phosphorescent emitters. The expression “fluorescent emitter” relates to materials or compounds which undergo a radiative transition from an excited singlet state to its ground state. The expression “phosphorescent emitter” as used in the present application relates to luminescent materials or compounds containing transition metals. These typically include materials where the emission of light is caused by spin-forbidden transition(s), for example transitions from excited triplet and/or quintuplet states.

According to quantum mechanics, the transition from excited states having high spin multiplicity, for example from excited triplet states, to the ground state is forbidden. However, the presence of a heavy atom, for example iridium, osmium, platinum and europium, ensures strong spin-orbit coupling, meaning that the excited singlet and triplet become mixed, and so the triplet gains a certain singlet character, and luminance can be efficient when the singlet-triplet mixture leads to a rate of radiative decay faster than the non-radiative outcome. This mode of emission can be achieved with metal complexes, as reported by Baldo et al. in Nature 395, 151-154 (1998).

Particular preference is given to an emitter selected from the group of the fluorescent emitters.

Many examples of fluorescent emitters have already been disclosed, for example styrylamine derivatives in JP 2913116 B and WO 2001/021729 A1, and indenofluorene derivatives in WO 2008/006449 and WO 2007/140847.

The fluorescent emitters are preferably polyaromatic compounds, for example 9,10-di(2-naphthylanthracene) and other anthracene derivatives, derivatives of tetracene, xanthene, perylene, for example 2,5,8,11-tetra-t-butylperylene, phenylene, e.g. 4,4′-(bis(9-ethyl-3-carbazovinylene)-1,1′-biphenyl, fluorene, arylpyrenes (US 2006/0222886), arylenevinylenes (U.S. Pat. No. 5,121,029, U.S. Pat. No. 5,130,603), derivatives of rubrene, coumarin, rhodamine, quinacridone, for example N,N′-dimethylquinacridone (DMQA), dicyanomethylenepyran, for example 4-(dicyanoethylene)-6-(4-dimethylaminostyryl-2-methyl)-4H-pyran (DCM), thiopyrans, polymethine, pyrylium and thiapyrylium salts, periflanthene, indenoperylene, bis(azinyl)imine-boron compounds (US 2007/0092753 A1), bis(azinyl)methane compounds and carbostyryl compounds.

Further preferred fluorescent emitters are described in C. H. Chen et al.: “Recent developments in organic electroluminescent materials” Macromol. Symp. 125, (1997), 1-48 and “Recent progress of molecular organic electroluminescent materials and devices” Mat. Sci. and Eng. R, 39 (2002), 143-222.

Further preferred fluorescent emitters are selected from the class of the monostyrylamines, the distyrylamines, the tristyrylamines, the tetrastyrylamines, the styrylphosphines, the styryl ethers and the arylamines.

A monostyrylamine is understood to mean a compound containing one substituted or unsubstituted styryl group and at least one preferably aromatic amine. A distyrylamine is understood to mean a compound containing two substituted or unsubstituted styryl groups and at least one preferably aromatic amine. A tristyrylamine is understood to mean a compound containing three substituted or unsubstituted styryl groups and at least one preferably aromatic amine. A tetrastyrylamine is understood to mean a compound containing four substituted or unsubstituted styryl groups and at least one preferably aromatic amine. The styryl groups are more preferably stilbenes which may also have further substitution. The corresponding phosphines and ethers are defined analogously to the amines. For the purposes of the present application, an arylamine or an aromatic amine is understood to mean a compound containing three substituted or unsubstituted aromatic or heteroaromatic ring systems bonded directly to the nitrogen. At least one of these aromatic or heteroaromatic ring systems is preferably a fused ring system preferably having at least 14 aromatic ring atoms. Preferred examples of these are aromatic anthracenamines, aromatic anthracenediamines, aromatic pyrenamines, aromatic pyrenediamines, aromatic chrysenamines and aromatic chrysenediamines. An aromatic anthracenamine is understood to mean a compound in which one diarylamino group is bonded directly to an anthracene group, preferably in the 9 position. An aromatic anthracenediamine is understood to mean a compound in which two diarylamino groups are bonded directly to an anthracene group, preferably in the 9,10 positions. Aromatic pyrenamines, pyrenediamines, chrysenamines and chrysenediamines are defined analogously thereto, where the diarylamino groups in the pyrene are bonded preferably in the 1 position or in 1,6 positions.

Further preferred fluorescent emitters are selected from indenofluorenamines and indenofluorenediamines, for example according to WO 2006/122630, benzoindenofluorenamines and benzoindenofluorenediamines, for example according to WO 2008/006449, and dibenzoindenofluorenamines and dibenzoindenofluorenediamines, for example according to WO 2007/140847.

Examples of emitters from the class of the styrylamines are substituted or unsubstituted tristilbenamines or the dopants described in WO 2006/000388, WO 2006/058737, WO 2006/000389, WO 2007/065549 and WO 2007/115610. Distyrylbenzene and distyrylbiphenyl derivatives are described in U.S. Pat. No. 5,121,029. Further styrylamines can be found in US 2007/0122656 A1.

Particularly preferred styrylamine emitters and triarylamine emitters are the compounds of the formulae (1) to (6), as disclosed in U.S. Pat. No. 7,250,532 B2, DE 102005058557 A1, CN 1583691 A, JP 08053397 A, U.S. Pat. No. 6,251,531 B1 and US 2006/210830 A.

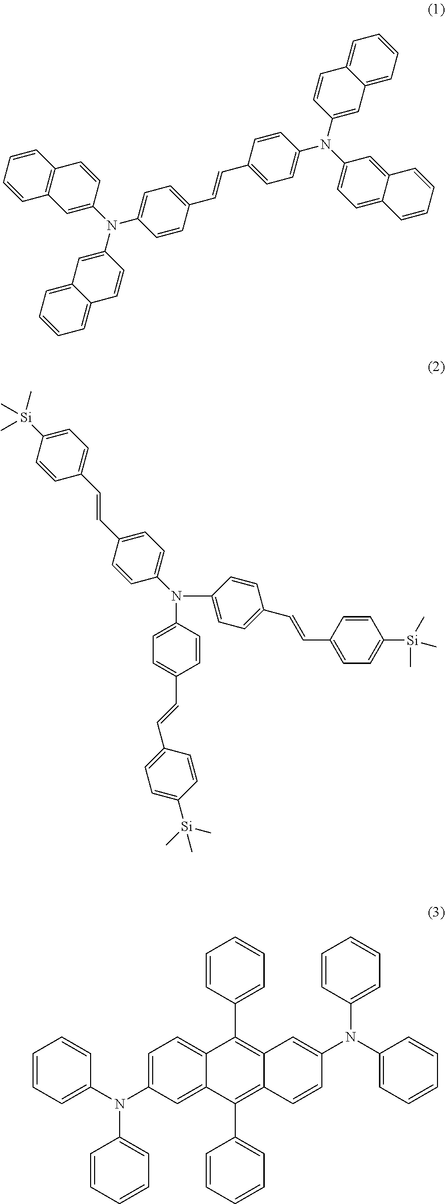

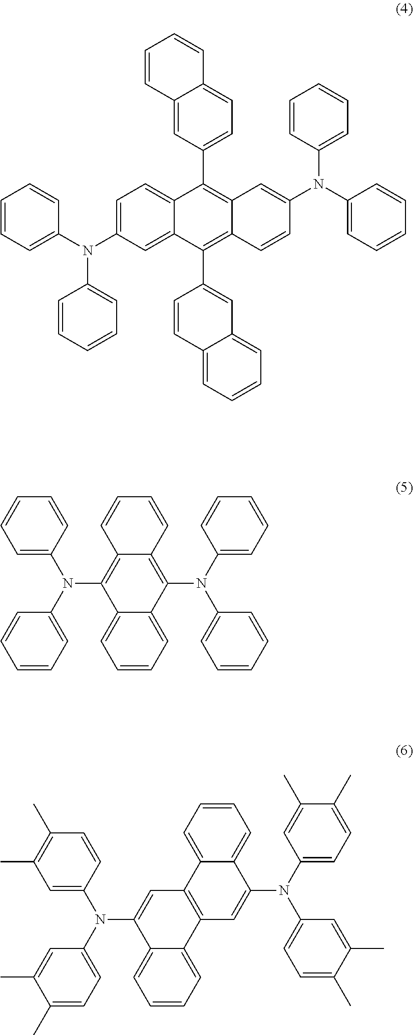

Further preferred fluorescent emitters are selected from the group of the triarylamines, as disclosed, for example, in EP 1957606 A1 and US 2008/0113101 A1.

Further preferred fluorescent emitters are selected from the derivatives of naphthalene, anthracene, tetracene, fluorene, periflanthene, indenoperylene, phenanthrene, perylene (US 2007/0252517 A1), pyrene, chrysene, decacycline, coronene, tetraphenylcyclopentadiene, pentaphenylcyclopentadiene, fluorene, spirobifluorene, rubrene, coumarin (U.S. Pat. No. 4,769,292, U.S. Pat. No. 6,020,078, US 2007/0252517 A1), pyran, oxazone, benzoxazole, benzothiazole, benzimidazole, pyrazine, cinnamic esters, diketopyrrolopyrrole, acridone and quinacridone (US 2007/0252517 A1).

Among the anthracene compounds, 9,10-substituted anthracenes, for example 9,10-diphenylanthracene and 9,10-bis(phenylethynyl)anthracene, are particularly preferred. 1,4-Bis(9′-ethynylanthracenyl)benzene is also a preferred dopant.

More preferably, one emitter in the emitter layer is selected from the group of the blue-fluorescing emitters.

More preferably, one emitter in the emitter layer is selected from the group of the green-fluorescing emitters.

More preferably, one emitter in the emitter layer is selected from the group of the yellow-fluorescing emitters.

More preferably, one emitter in the emitter layer is selected from the group of the red-fluorescing emitters.

A red-fluorescing emitter is preferably selected from the group of the perylene derivatives, for example in the following structure of the formula (7), as disclosed, for example, in US 2007/0104977 A1:

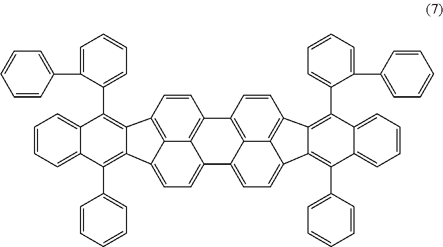 [SMILES: c1ccc(-c2ccccc2-c2c3c(c(-c4ccccc4)c4ccccc24)-c2ccc4c5ccc6c7c(ccc(c8ccc-3c2c48)c75)-c2c-6c(-c3ccccc3)c3ccccc3c2-c2ccccc2-c2ccccc2)cc1]

Preferred emitting repeat units are those which are selected from the following formulae:

vinyltriarylamines of the formula (I), as disclosed, for example, in DE-A-10 2005 060 473:

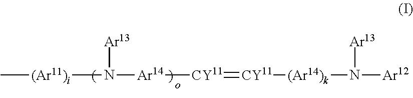

in which
Ar¹¹ is independently a mono- or polycyclic aryl or heteroaryl group optionally mono- or polysubstituted by R¹¹ radicals,
Ar¹² is independently a mono- or polycyclic aryl or heteroaryl group optionally mono- or polysubstituted by R¹² radicals,
Ar¹³ is independently a mono- or polycyclic aryl or heteroaryl group optionally mono- or polysubstituted by R¹³ radicals,
Ar¹⁴ is independently a mono- or polycyclic aryl or heteroaryl group optionally mono- or polysubstituted by R¹⁴ radicals,
Y¹¹ is independently selected from the group of hydrogen, fluorine, chlorine, or carbyl or hydrocarbyl having 1 to 40 atoms, which are optionally substituted and which optionally contain one or more heteroatoms, and in which two Y¹¹ groups or one Y¹¹ group and one adjacent R¹¹, R¹⁴, Ar¹¹ or Ar¹⁴ together optionally form an aromatic mono- or polycyclic ring system, R¹¹ to R¹⁴ are independently hydrogen, halogen, —CN, —NC, —NCO, —NCS, —OCN, —SCN, —C(═O)NR⁰R⁰⁰, —C(═O)X⁰, —C(═O)R⁰, —NH₂, —NR⁰R⁰⁰, —SH, —SR⁰, —SO₃H, —SO₂R⁰, —OH, —NO₂, —CF₃, —SF₅, optionally substituted silyl, or carbyl or hydrocarbyl having 1 to 40 carbon atoms, which are optionally substituted and which optionally contain one or more heteroatoms, and in which two or more of the R¹¹ to R¹⁴ radicals together optionally form an aliphatic or aromatic, mono- or polycyclic ring system, and in which
R¹¹, R¹² and R¹³ may also be a covalent bond in a polymer,
X⁰, R⁰ and R⁰⁰ have one of the meanings defined in formula (I),
i is independently 1, 2 or 3,
k is independently 1, 2 or 3,
o is independently 0 or 1.

Further preferred emitting repeat units are 1,4-bis(2-thienylvinyl)benzenes of the formula (II), as disclosed, for example, in WO 2005/030827 A:

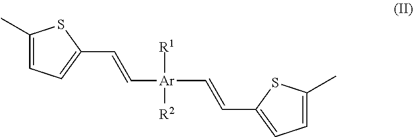

in which R¹ and R² are as defined formula (I) and Ar is as defined for Ar¹¹ in formula (I).

Further preferred emitting repeat units are 1,4-bis(2-arylenevinyl)benzenes of the formula (III), as disclosed, for example, in WO 00/46321 A:

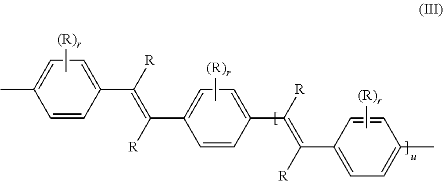

in which r and R are each as defined above and u is 0 or 1.

Further preferred emitting repeat units are radicals of the formula (IV):

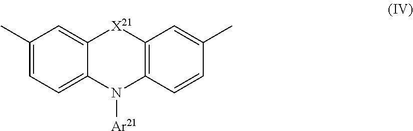

in which
X²¹ is O, S, SO₂, C(R^{x})₂ or N—R^{x}, in which R^{x} is aryl or substituted aryl or aralkyl having 6 to 40 carbon atoms, or alkyl having 1 to 24 carbon atoms, preferably aryl having 6 to 24 carbon atoms, more preferably alkylated aryl having 6 to 24 carbon atoms,
Ar²¹ is optionally substituted aryl or heteroaryl having 6 to 40, preferably 6 to 24 and more preferably 6 to 14 carbon atoms.

Further preferred emitting repeat units are radicals of the formulae (V) and (VI):

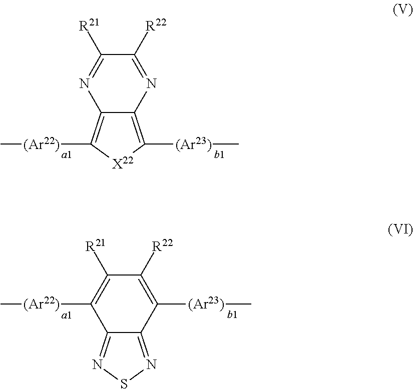

in which
X²² is R²³C═CR²³ or S, in which each R²³ is independently selected from the group of hydrogen, alkyl, aryl, perfluoroalkyl, thioalkyl, cyano, alkoxy, heteroaryl, alkylaryl or arylalkyl,
R²¹ and R²² are the same or different and are each a substituent group,
Ar²² and Ar²³ are each independently a divalent aromatic or heteroaromatic ring system which has 2 to 40 carbon atoms and is optionally substituted by one or more R²¹ radicals, and
a1 and b1 are independently 0 or 1.

Further preferred emitting repeat units are radicals of the formulae (VII) and (VIII):

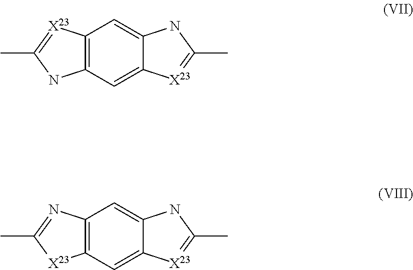

in which

### X²³ is NH, O or S,

Further preferred emitting repeat units are radicals of the formulae (IX) to (XIX):

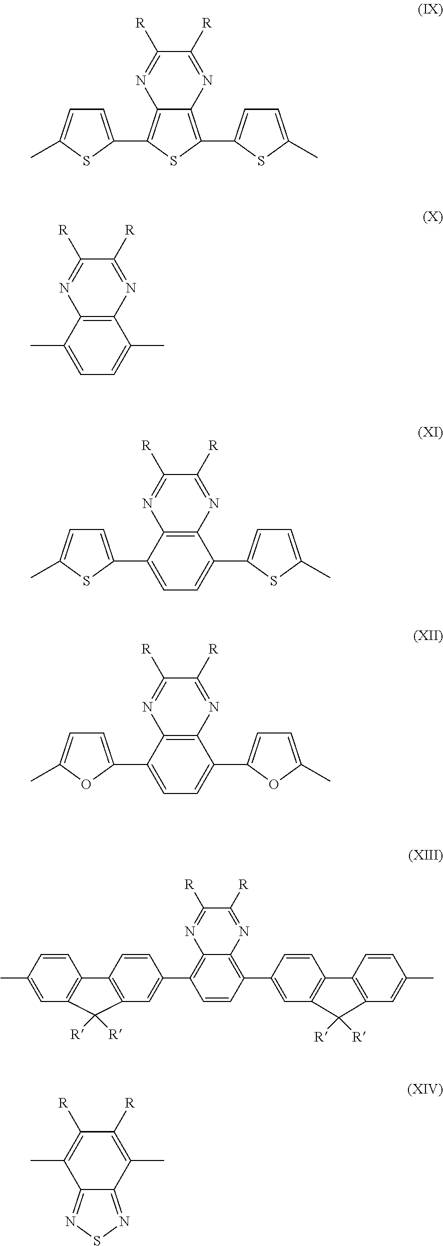

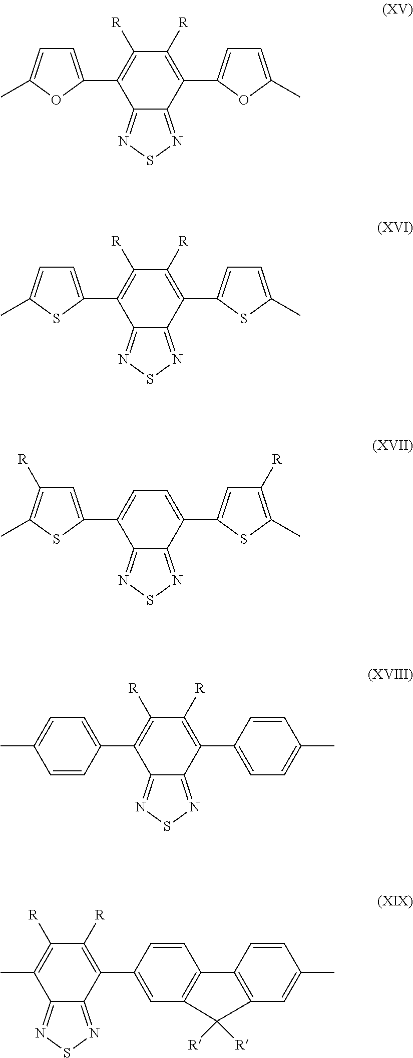

in which
R and R′ have one of the definitions given above and are preferably independently hydrogen, alkyl, aryl, perfluoroalkyl, thioalkyl, cyano, alkoxy, heteroaryl, alkylaryl or arylalkyl, R more preferably being hydrogen, phenyl or alkyl having 1, 2, 3, 4, 5 or 6 carbon atoms, and R′ more preferably being n-octyl or n-octyloxy.

Further preferred emitting repeat units are radicals of the formulae (XX) to (XXIX):

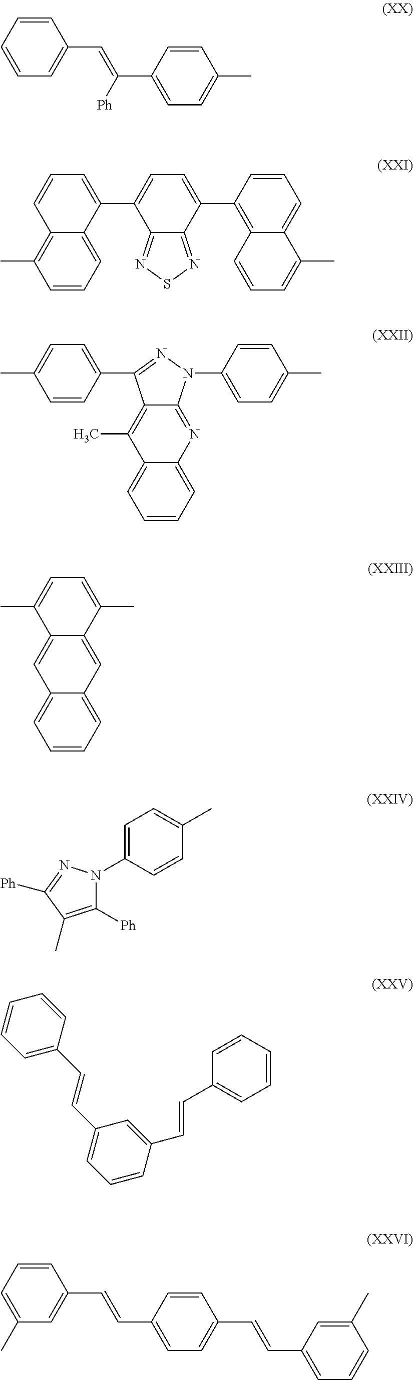

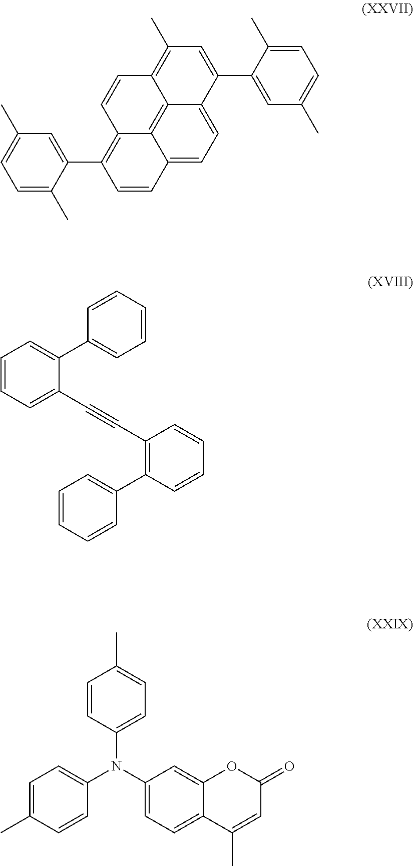

in which
Ph is phenyl.

Particular preference is likewise given to an emitter in the emitter layer selected from the group of the phosphorescent emitters.

Examples of phosphorescent emitters are disclosed in WO 00/70655, WO 01/41512, WO 02/02714, WO 02/15645, EP 1191613, EP 1191612, EP 1191614 and WO 2005/033244.

In general, all phosphorescent complexes as used according to the prior art and as known to those skilled in the art in the field of organic electroluminescence are suitable, and the person skilled in the art will be able to use further phosphorescent complexes without exercising inventive skill.

The phosphorescent emitter may be a metal complex, preferably of the formula M(L)_{z} in which M is a metal atom, L independently at each instance is an organic ligand bonded or coordinated to M via one, two or more positions, and z is an integer 1, preferably 1, 2, 3, 4, 5 or 6, and in which these groups are optionally joined to a polymer via one or more, preferably one, two or three, positions, preferably via the ligands L.

M is especially a metal atom selected from transition metals, preferably from transition metals of group VIII, the lanthanides and the actinides, more preferably from Rh, Os, Ir, Pt, Pd, Au, Sm, Eu, Gd, Tb, Dy, Re, Cu, Zn, W, Mo, Pd, Ag and Ru and especially from Os, Ir, Ru, Rh, Re, Pd and Pt. M may also be Zn.

Preferred ligands are 2-phenylpyridine derivatives, 7,8-benzoquinoline derivatives, 2-(2-thienyl)pyridine derivatives, 2-(1-naphthyl)pyridine derivatives or 2-phenylquinoline derivatives. These compounds may each be substituted, for example by fluorine or trifluoromethyl substituents for blue. Secondary ligands are preferably acetylacetonate or picric acid.

Especially suitable are complexes of Pt or Pd with tetradentate ligands of the formula (8), as disclosed, for example, in US 2007/0087219 A1, in which R¹ to R¹⁴ and Z¹ to Z⁵ are as defined in the reference, Pt-porphyrin complexes having an enlarged ring system (US 2009/0061681 A1) and Ir complexes, for example 2,3,7,8,12,13,17,18-octaethyl-21H,23H-porphyrin-Pt(II), tetraphenyl-Pt(II)-tetrabenzoporphyrin (US 2009/0061681 A1), cis-bis(2-phenylpyridinato-N,C2′)Pt(II), cis-bis(2-(2′-thienyl)pyridinato-N,C3′)Pt(II), cis-bis(2-(2′-thienyl)quinolinato-N,C5′)Pt(II), (2-(4,6-difluorophenyl)pyridinato-N,C2′)Pt(II) acetylacetonate or tris(2-phenylpyridinato-N,C2′)Ir(III) (Ir(ppy)₃, green), bis(2-phenylpyridinato-N,C2)Ir(III) acetylacetonate (Ir(ppy)₂ acetylacetonate, green, US 2001/0053462 A1, Baldo, Thompson et al. Nature 403, (2000), 750-753), bis(1-phenylisoquinolinato-N,C2′)(2-phenylpyridinato-N,C2′)iridium(III), bis(2-phenylpyridinato-N,C2′(1-phenylisoquinolinato-N,C2′)iridium(III), bis(2-(2′-benzothienyl)pyridinato-N,C3′)iridium(III) acetylacetonate, bis(2-(4′,6′-difluorophenyl)pyridinato-N,C2′)iridium(III) picolinate (Firpic, blue), bis(2-(4′,6′-difluorophenyl)pyridinato-N,C2′)Ir(III) tetrakis(1-pyrazolyl)borate, tris(2-(biphenyl-3-yl)-4-tart-butylpyridine)iridium(III), (ppz)₂Ir(5phdpym) (US 2009/0061681 A1), (45ooppz)₂Ir(5phdpym) (US 2009/0061681 A1), derivatives of 2-phenylpyridine-Ir complexes, for example iridium(III) bis(2-phenylquinolyl-N,C2′) acetylacetonate (PQIr), tris(2-phenylisoquinolinato-N,C)Ir(III) (red), bis(2-(2′-benzo[4,5-a]thienyl)pyridinato-N,C3)Ir acetylacetonate ([Btp2Ir(acac)], red, Adachi et al. Appl. Phys. Lett. 78 (2001), 1622-1624).

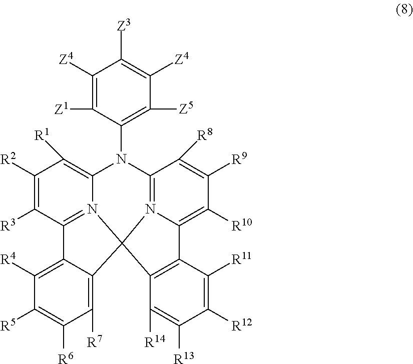

Likewise suitable are complexes of trivalent lanthanides, for example Tb³⁺ and Eu³⁺ (J. Kido et al. Appl. Phys. Lett. 65 (1994), 2124, Kido et al. Chem, Lett. 657, 1990, US 2007/0252517 A1) or phosphorescent complexes of Pt(II), Ir(I), Rh(I) with maleonitrile dithiolate (Johnson et al., JACS 105, 1983, 1795), Re(I)-tricarbonyldiimine complexes (inter alia Wrighton, JACS 96, 1974, 998), Os(II) complexes with cyano ligands and bipyridyl or phenanthroline ligands (Ma et al., Synth. Metals 94, 1998, 245) or Alq₃.

Further phosphorescent emitters having tridentate ligands are disclosed in U.S. Pat. No. 6,824,895 and U.S. Pat. No. 7,029,766. Red-emitting phosphorescent complexes are disclosed in U.S. Pat. No. 6,835,469 and U.S. Pat. No. 6,830,828.

Particularly preferred phosphorescent emitters are compounds of the following formulae (9) and (10) and further compounds as disclosed, for example, in US 2001/0053462 A1 and WO 2007/095118 A1:

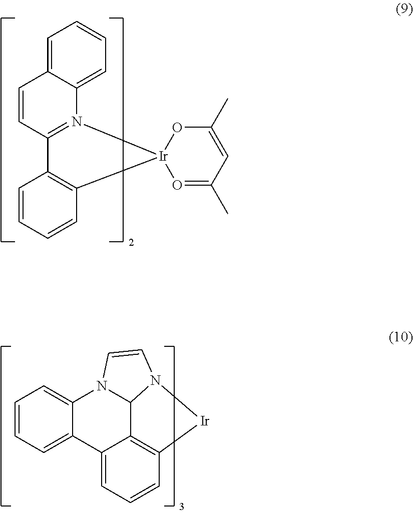

Further derivatives are described in U.S. Pat. No. 7,378,162 B2, U.S. Pat. No. 6,835,469 B2 and JP 2003/253145 A.

Particular preference is given to an emitter in the emitter layer selected from the group of the organometallic complexes.

In addition to metal complexes mentioned elsewhere in this document, a suitable metal complex according to the present invention is selected from transition metals, rare earth elements, lanthanides and actinides. The metal is preferably selected from Ir, Ru, Os, Eu, Au, Pt, Cu, Zn, Mo, W, Rh, Pd and Ag.

The proportion of the emitter structural units in the hole-conducting polymer which is used in the interlayer is generally between 0.01 and 20 mol %, preferably between 0.5 and 10 mol %, more preferably between 1 and 8 mol % and especially between 1 and 5 mol %.

The copolymers which form the interlayer, i.e. the second emitter layer, must have hole-conducting properties. This profile of properties can be created through the selection of suitable repeat units having hole transport properties. Preferably, the polymer of the interlayer has further repeat units which form the polymer backbone.

In principle, any hole transport material (HTM) known to those skilled in the art can be used as repeat unit in the polymer according to the present invention. Such an HTM is preferably selected from amines, triarylamines, thiophenes, carbazoles, phthalocyanines, porphyrins and isomers and derivatives thereof. The HTM is more preferably selected from amines, triarylamines, thiophenes, carbazoles, phthalocyanines and porphyrins.

Suitable HTM units are phenylenediamine derivatives (U.S. Pat. No. 3,615,404), arylamine derivatives (U.S. Pat. No. 3,567,450), amino-substituted chalcone derivatives (U.S. Pat. No. 3,526,501), styrylanthracene derivatives (JP A 56-46234), polycyclic aromatic compounds (EP 1009041), polyarylalkane derivatives (U.S. Pat. No. 3,615,402), fluorenone derivatives (JP A 54-110837), hydrazone derivatives (U.S. Pat. No. 3,717,462), stilbene derivatives (JP A 61-210363), silazane derivatives (U.S. Pat. No. 4,950,950), polysilanes (JP A 2-204996), aniline copolymers (JP A 2-282263), thiophene oligomers, polythiophenes, PVK, polypyrroles, polyanilines and further copolymers, porphyrin compounds (JP A 63-2956965), aromatic dimethylidene-like compounds, carbazole compounds, for example CDBP, CSP, mCP, aromatic tertiary amine and styrylamine compounds (U.S. Pat. No. 4,127,412) and monomeric triarylamines (U.S. Pat. No. 3,180,730).

Preference is given to aromatic tertiary amines containing at least two tertiary amine units (U.S. Pat. No. 4,720,432 and U.S. Pat. No. 5,061,569), for example 4,4′-bis[N-(1-naphthyl)-N-phenylamino]biphenyl (NPD) (U.S. Pat. No. 5,061,569) or MTDATA (JP A 4-308688), N,N,N′,N′-tetra(4-biphenyl)diaminobiphenylene (TBDB), 1,1-bis(4-di-p-tolylaminophenyl)cyclohexane (TAPC), 1,1-bis(4-di-p-tolylaminophenyl)-3-phenylpropane (TAPPP), 1,4-bis[2-[4-[N,N-di(p-tolyl)amino]phenyl]vinyl]benzene (BDTAPVB), N,N,N′,N′-tetra-p-tolyl-4,4′-diaminobiphenyl (TTB), TPD, N,N,N′,N′-tetraphenyl-4,4′″-diamino-1,1′:4′,1″:4″,1″-quaterphenyl, and likewise tertiary amines containing carbazole units, for example 4-(9H-carbazol-9-yl)-N,N-bis[4-(9H-carbazol-9-yl)phenyl]benzenamine (TCTA). Preference is likewise given to hexaazatriphenylene compounds according to US 2007/0092755 A1.

Particular preference is given to the following triarylamine compounds of the formulae (11) to (16) which may also be substituted, as disclosed, for example, in EP 1162193 A1, EP 650955 A1, in Synth. Metals 1997, 91(1-3), 209, in DE 19646119 A1, WO 2006/122630 A1, EP 1860097 A1, EP 1834945 A1, JP 08/053397 A, U.S. Pat. No. 6,251,531 B1 and WO 2009/041635.

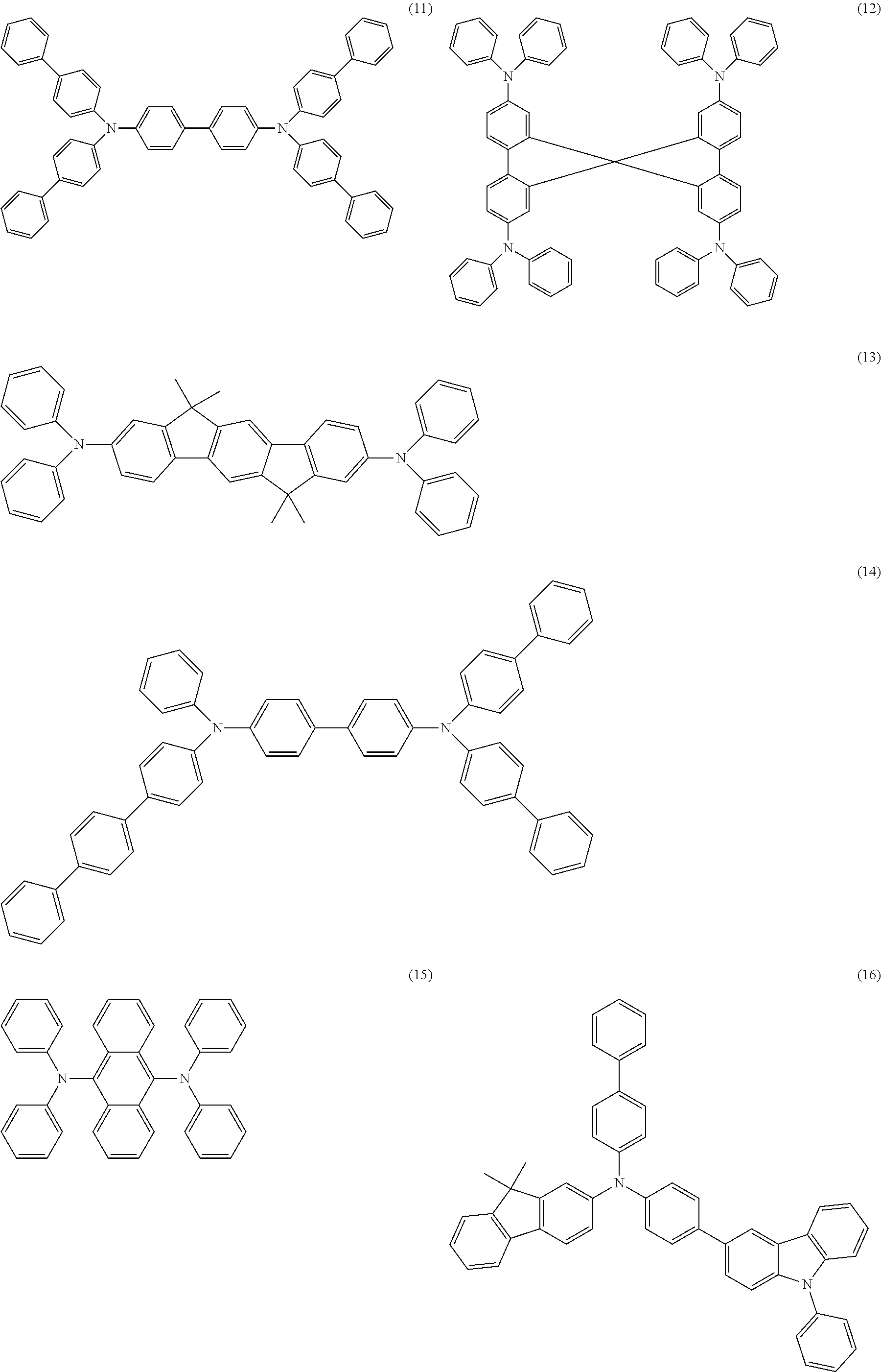

Further preferred HTM units are, for example, triarylamine, benzidine, tetraaryl-para-phenylenediamine, carbazole, azulene, thiophene, pyrrole and furan derivatives, and additionally O-, S- or N-containing heterocycles.

More preferably, the HTM units are selected from the following repeat unit of the formula (17):

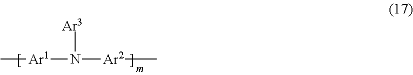

where
Ar¹, which may be the same or different, independently when in different repeat units, are a single bond or an optionally substituted monocyclic or polycyclic aryl group,
Ar², which may be the same or different, independently when in different repeat units, are an optionally substituted monocyclic or polycyclic aryl group,
Ar³, which may be the same or different, independently when in different repeat units, are an optionally substituted monocyclic or polycyclic aryl group, and
m is 1, 2 or 3.

Particularly preferred units of the formula (17) are selected from the group of the following formulae (18) to (20):

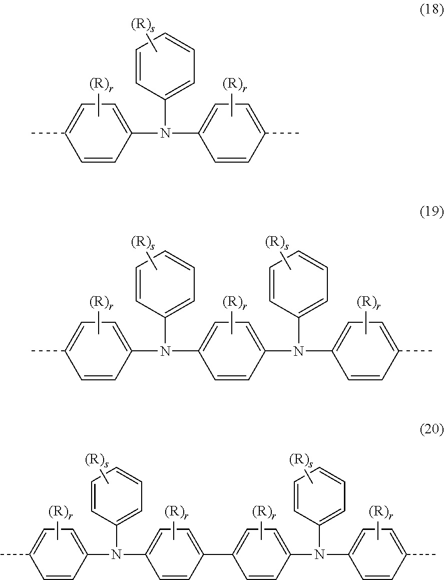

where
R, which may be the same or different at each instance, is selected from H, substituted or unsubstituted aromatic or heteroaromatic group, alkyl group, cycloalkyl group, alkoxy group, aralkyl group, aryloxy group, arylthio group, alkoxycarbonyl group, silyl group, carboxyl group, halogen atom, cyano group, nitro group and hydroxyl group,
r is 0, 1, 2, 3 or 4 and
s is 0, 1, 2, 3, 4 or 5.

A further preferred interlayer polymer contains at least one repeat unit of the following formula (21):

-(T¹)_{c}-(Ar⁴)_{d}-(T²)_{c}-(Ar⁵)₁ (21)

where
T¹ and T² are each independently selected from thiophene, selenophene, thieno[2,3b]thiophene, thieno[3,2b]thiophene, dithienothiophene, pyrrole, aniline, all optionally substituted by R⁵,
R⁵ independently at each instance is selected from halogen, —CN, —NC, —NCO, —NCS, —OCN, SCN, C(═O)NR⁰R⁰⁰, —C(═O)X, —C(═O)R⁰, —NH₂, —NR⁰R⁰⁰, SH, SR⁰, —SO₃H, —SO₂R⁰, —OH, —NO₂, —CF₃, —SF₅, optionally substituted silyl, or carbyl or hydrocarbyl which has 1 to 40 carbon atoms and is optionally substituted and optionally contains one or more heteroatoms,
R⁰ and R⁰⁰ are independently H or an optionally substituted carbyl or hydrocarbyl group optionally containing one or more heteroatoms,
Ar⁴ and Ar⁵ are independently monocyclic or polycyclic aryl or heteroaryl which is optionally substituted and optionally fused to the 2,3 positions of one or both of the adjacent thiophene or selenophene groups,
c and e are independently 0, 1, 2, 3 or 4, where 1<c+e≦6, and
d and f are independently 0, 1, 2, 3 or 4.

The T¹ and T² groups are preferably selected from

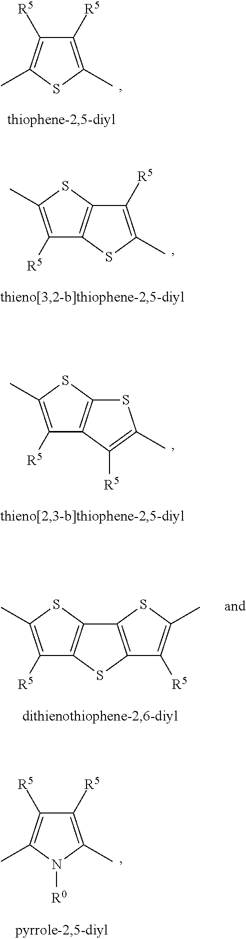

in which R⁰ and R⁵ can assume the same definitions as R⁰ and R⁵ in formula (21).

Preferred units of the formula (21) are selected from the group of the following formulae:

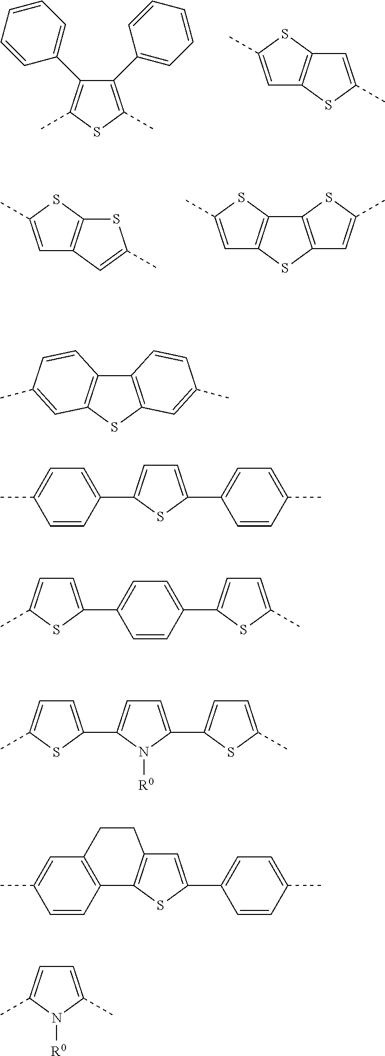

where R⁰ can assume the same definitions as R⁵ in formula (21).

The proportion of the HTM repeat units in the hole-conducting polymer which is used in the interlayer is preferably between 10 and 99 mol %, more preferably between 20 and 80 mol % and especially between 30 and 60 mol %.

As well as the emitter repeat units and the hole-conducting repeat units, the copolymers used in the interlayer preferably also have further structural units which form the backbone of the copolymer.

Preferred repeat units which form the polymer backbone are aromatic or heteroaromatic structures having 6 to 40 carbon atoms. These are, for example, 4,5-dihydropyrene derivatives, 4,5,9,10-tetrahydropyrene derivatives, fluorene derivatives as disclosed, for example, in U.S. Pat. No. 5,962,631, WO 2006/052457 A2 and WO 2006/118345 A1, 9,9′-spirobifluorene derivatives as disclosed, for example, in WO 2003/020790 A1, 9,10-phenanthrene derivatives as disclosed, for example, in WO 2005/104264 A1, 9,10-dihydrophenanthrene derivatives as disclosed, for example, in WO 2005/014689 A2, 5,7-dihydrodibenzoxepine derivatives and cis- and trans-indenofluorene derivatives as disclosed, for example, in WO 2004/041901 A1 and WO 2004/113412 A2, and binaphthylene derivatives as disclosed, for example, in WO 2006/063852 A1, and additionally units such as, for example, benzofluorene, dibenzofluorene, benzothiophene, dibenzofluorene and derivatives thereof, as disclosed, for example, in WO 2005/056633 A1, EP 1344788 A1, WO 2007/043495 A1, WO 2005/033174 A1, WO 2003/099901 A1 and DE 102006003710.

Particularly preferred repeat units for the polymer backbone are repeat units of the following formula (22):

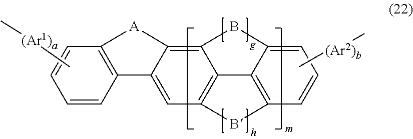

where
A, B and B′ are independently, and independently of one another in the case of multiple instances, a divalent group, preferably selected from —CR¹R²—,
—NR¹—, —PR¹—, —O—, —S—, —SO—, —SO₂—, —CO—, —CS—, —CSe—, —P(═O)R¹—, —P(═S)R¹— and —SiR¹R²—,
R¹ and R² are independently identical or different groups selected from H, halogen, —CN, —NC, —NCO, —NCS, —OCN, —SCN, —C(═O)NR⁰R⁰⁰, —C(═O)X, —C(═O)R⁰, —NH₂, —NR⁰R⁰⁰, —SH, —SR⁰, —SO₃H, —SO₂R⁰, —OH, —NO₂, —CF₃, SF₅, optionally substituted silyl, or carbyl or hydrocarbyl which has 1 to 40 carbon atoms and is optionally substituted and optionally contains one or more heteroatoms, and the R′ and R² groups optionally form a Spiro group together with the fluorene moiety to which they are bonded,
X is halogen,
R⁰ and R⁰⁰ are independently H or an optionally substituted carbyl or hydrocarbyl group optionally containing one or more heteroatoms,
each g is independently 0 or 1 and the respective corresponding h in the same subunit is the other of 0 and 1,
m is an integer ≧1,
Ar¹ and Ar² are independently mono- or polycyclic aryl or heteroaryl which is optionally substituted and optionally fused to the 7,8 positions or 8,9 positions of the indenofluorene group, and
a and b are independently 0 or 1.

If the R¹ and R² groups together with the fluorene group to which they are bonded form a Spiro group, the structure is preferably a spirobifluorene.

The group of the formula (22) is preferably selected from the following formulae (23) to (27):

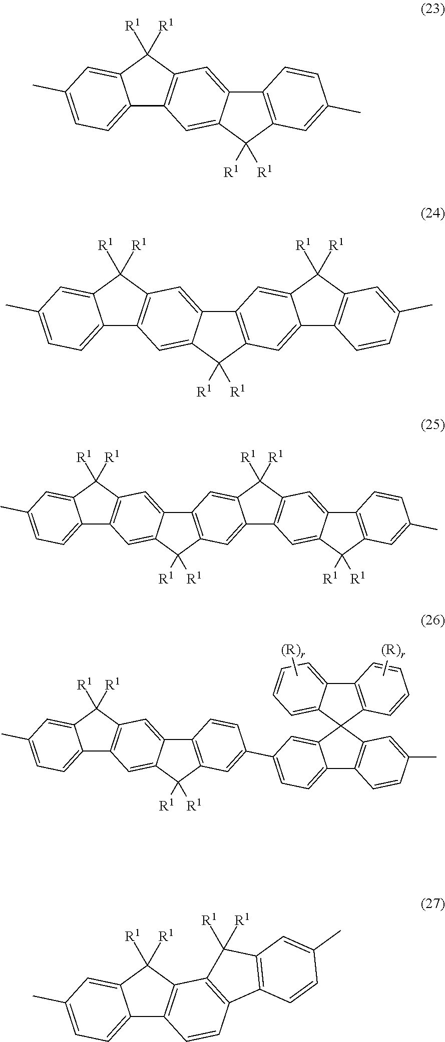

in which R¹ is as defined in formula (22), r is 0, 1, 2, 3 or 4 and R may assume one of the definitions of R¹.

Preferably, R is F, Cl, Br, I, —CN, —NO₂, —NCO, —NCS, —OCN, —SCN, —C(═O)NR⁰R⁰⁰, —C(═O)X, —C(═O)R⁰, —NR⁰R⁰⁰, optionally substituted silyl, aryl or heteroaryl having 4 to 40 and preferably 6 to 20 carbon atoms, or straight-chain, branched or cyclic alkyl, alkoxy, alkylcarbonyl, alkoxycarbonyl, alkylcarbonyloxy or alkoxycarbonyloxy having 1 to 20 and preferably 1 to 12 carbon atoms, in which one or more hydrogen atoms are optionally replaced by F or Cl and in which R⁰, R⁰⁰ and X are as defined above in relation to formula (22).

The group of the formula (22) is more preferably selected from the following formulae (28) to (31):

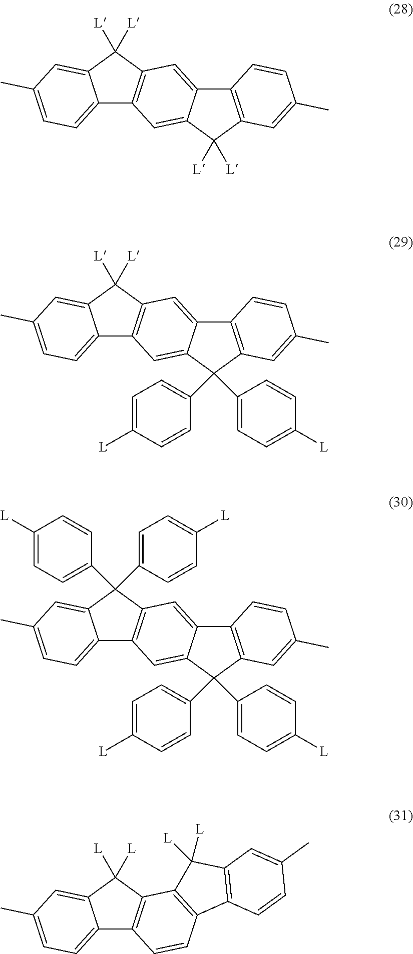

where
L is H, halogen or optionally fluorinated linear or branched alkyl or alkoxy having 1 to 12 carbon atoms and preferably H, F, methyl, i-propyl, t-butyl, n-pentoxy or trifluoromethyl and
L′ is optionally fluorinated linear or branched alkyl or alkoxy having 1 to 12 carbon atoms and preferably n-octyl or n-octyloxy.

In a further preferred embodiment of the present invention, the polymer in the interlayer is a non-conjugated or partly conjugated polymer.

A particularly preferred non-conjugated or partly conjugated polymer in the interlayer contains a non-conjugated repeat unit for the polymer backbone.

The non-conjugated repeat unit for the polymer backbone unit is preferably an indenofluorene unit of the following formulae (32) and (33), as disclosed, for example, in WO 2010/136110:

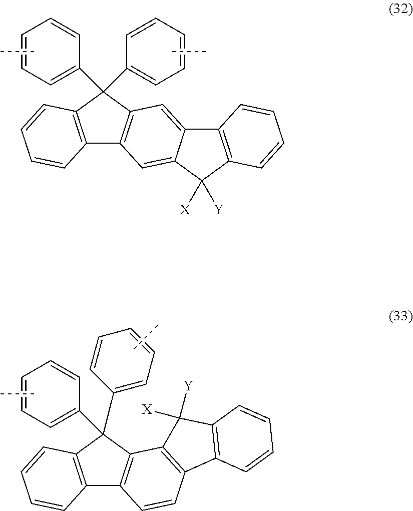

where X and V are independently selected from the group consisting of H, F, a C₁₋₄₀ alkyl group, a C₂₋₄₀-alkenyl group, a C₂₋₄₀-alkynyl group, an optionally substituted C₆₋₄₀-aryl group and an optionally substituted 5- to 25-membered heteroaryl group.

Further preferred non-conjugated repeat units for the polymer backbone are selected from fluorene, phenanthrene, dihydrophenanthrene and indenofluorene derivatives of the following formulae as disclosed, for example, in WO 2010/136111:

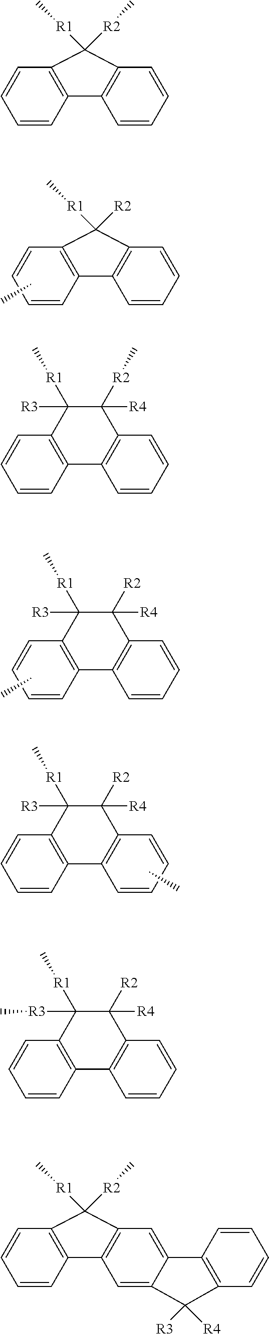

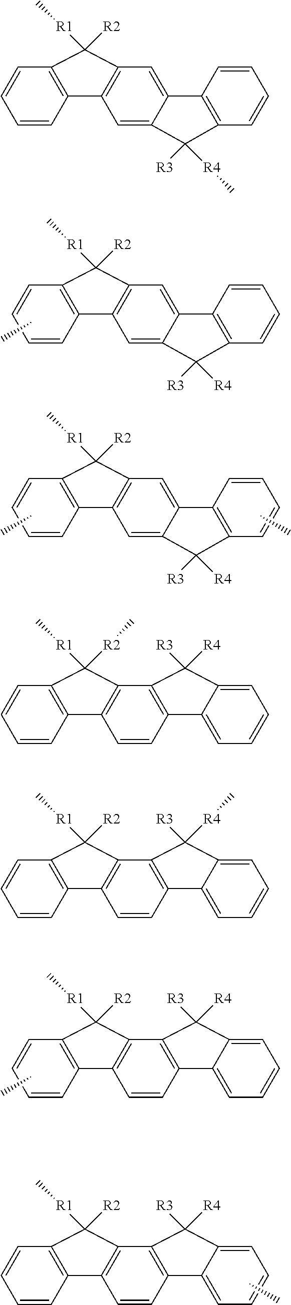

where R1-R4 may assume the same definitions as X and Y in the formulae (32) and (33).

The proportion of the repeat units which form the polymer backbone in the hole-conducting polymer which is used in the interlayer is preferably between 10 and 99 mol %, more preferably between 20 and 80 mol % and especially between 30 and 60 mol %.

The semiconductive organic material for the first emitter layer may be a polymeric matrix material which contains one or more different emitters incorporated within the polymer, or may be a polymeric and non-emitting matrix material into which one or more low molecular weight emitters have been mixed, or may be mixtures of different polymers having emitters incorporated within the polymer skeleton, or may be mixtures of different non-emitting matrix polymers with different low molecular weight emitters, or may be mixtures of at least one low molecular weight matrix material with different low molecular weight emitters, or may be any desired combinations of these materials.

In a preferred embodiment, the emitter layer comprises a non-conjugated polymer containing at least one repeat unit containing an emitter group as described above. Examples of conjugated polymers containing metal complexes and the synthesis thereof are disclosed, for example, in EP 1138746 B1 and DE 102004032527 A1. Examples of conjugated polymers containing singlet emitters and the synthesis thereof are disclosed, for example, in DE 102005060473 A1 and WO 2010/022847.

In a further preferred embodiment, the emitter layer comprises a non-conjugated polymer containing at least one emitter group as described above and at least one pendant charge transport group. Examples of non-conjugated polymers containing a pendant metal complex and the synthesis thereof are disclosed, for example, in U.S. Pat. No. 7,250,226 B2, JP 2007/211243 A2, JP 2007/197574 A2, U.S. Pat. No. 7,250,226 B2 and JP 2007/059939 A. Examples of non-conjugated polymers containing a pendant singlet emitter and the synthesis thereof are disclosed, for example, in JP 2005/108556, JP 2005/285661 and JP 2003/338375.

In a further preferred embodiment, the emitter layer comprises a non-conjugated polymer containing at least one emitter group as described above as repeat unit and at least one repeat unit which forms the polymer backbone in the main chain, in which case the repeat units which form the polymer backbone may preferably be selected from the non-conjugated repeat units for the polymer backbone as described above for the interlayer polymer. Examples of non-conjugated polymers containing a metal complex in the main chain and the synthesis thereof are disclosed, for example, in WO 2010/149261 and WO 2010/136110.

In yet a further preferred embodiment, a material used for the emitter layer comprises a charge-transporting polymer matrix as well as the emitter(s). For fluorescent emitters or singlet emitters, this polymer matrix may be selected from a conjugated polymer preferably containing a non-conjugated polymer backbone as described above for the interlayer polymer and more preferably a conjugated polymer backbone as described above for the interlayer polymer. For phosphorescent emitters or triplet emitters, this polymer matrix is preferably selected from non-conjugated polymers which are a non-conjugated side chain polymer or a non-conjugated main chain polymer, e.g. polyvinylcarbazole (“PVK”), polysilane, copolymers containing phosphine oxide units or the matrix polymers as described, for example, in WO 2010/149261 and WO 2010/136110.

In yet a further preferred embodiment, the emitter layer comprises at least one low molecular weight emitter containing an emitter group as described above and at least one low molecular weight matrix material. Suitable low molecular weight matrix materials are materials from various substance classes.

Preferred matrix materials for fluorescent or singlet emitters are selected from the classes of the oligoarylenes (e.g. 2,2′,7,7′-tetraphenyispirobifluorene according to EP 676461 or dinaphthylanthracene), especially of the fused oligoarylenes containing aromatic groups, for example phenanthrene, tetracene, coronene, chrysene, fluorene, spirobifluorene, perylene, phthaloperylene, naphthaloperylene, decacyclene, rubrene, the oligoarylenevinylenes (e.g. 4,4′-bis(2,2-diphenylethenyl)-1,1′-biphenyl (DPVBI) or 4,4-bis-2,2-diphenylvinyl-1,1-spirobiphenyl (spiro-DPVBi) according to EP 676461), the polypodal metal complexes (for example according to WO 04/081017), especially metal complexes of 8-hydroxyquinoline, e.g. aluminum(III) tris(8-hydroxyquinoline) (aluminum quinolate, Alq₃) or bis(2-methyl-8-quinolinolato)-4-(phenylphenolinolato)aluminum, including with imidazole chelate (US 2007/0092753 A1) and quinoline-metal complexes, aminoquinoline metal complexes, benzoquinoline metal complexes, the hole-conducting compounds (for example according to WO 04/058911), the electron-conducting compounds, especially ketones, phosphine oxides, sulfoxides, etc. (for example according to WO 05/084081 and WO 05/084082), the atropisomers (for example according to WO 06/048268), the boronic acid derivatives (for example according to WO 06/117052) or the benzanthracenes (for example according to DE 102007024850).

Particularly preferred host materials are selected from the classes of the oligoarylenes comprising naphthalene, anthracene, benzanthracene and/or pyrene or atropisomers of these compounds, the ketones, the phosphine oxides and the sulfoxides. Very particularly preferred host materials are selected from the classes of the oligoarylenes comprising anthracene, benzanthracene and/or pyrene, or atropisomers of these compounds. For the purposes of the present application, an oligoarylene is understood to mean a compound in which at least three aryl or arylene groups are bonded to one another.

Particularly preferred low molecular weight matrix materials for singlet emitters are selected from benzanthracene, anthracene, triarylamine, indenofluorene, fluorene, spirobifluorene, phenanthrene, dihydrophenanthrene and the isomers and derivatives thereof.

Preferred low molecular weight matrix materials for phosphorescent or triplet emitters are N,N-biscarbazolyibiphenyl (GBP), carbazole derivatives (for example according to WO 05/039246, US 2005/0069729, JP 2004/288381, EP 1205527 and DE 102007002714), azacarbazoles (for example according to EP 1617710, EP 1617711, EP 1731584 and JP 2005/347160), ketones (for example according to WO 04/093207), phosphine oxides, sulfoxides and sulfones (for example according to WO 05/003253), oligophenylenes, aromatic amines (for example according to US 2005/0069729), bipolar matrix materials (for example according to WO 07/137725), 1,3,5-triazine derivatives (for example according to U.S. Pat. No. 6,229,012 B1, U.S. Pat. No. 6,225,467 B1, DE 10312675 A1, WO 9804007 A1 and U.S. Pat. No. 6,352,791 B1), silanes (for example according to WO 05/111172), 9,9-diarylfluorene derivatives (for example according to DE 102008017591), azaboroles or boronic esters (for example according to WO 06/117052), triazole derivatives, oxazoles and oxazole derivatives, imidazole derivatives, polyarylalkane derivatives, pyrazoline derivatives, pyrazolone derivatives, distyrylpyrazine derivatives, thiopyran dioxide derivatives, phenylenediamine derivatives, tertiary aromatic amines, styrylamines, amino-substituted chalcone derivatives, indoles, styrylanthracene derivatives, aryl-substituted anthracene derivatives, for example 2,3,5,6-tetramethylphenyl-1,4-(bisphthalimide) (TMPP, US 2007/0252517 A1), anthraquinodimethane derivatives, anthrone derivatives, fluorenone derivatives, fluorenylidenemethane derivatives, hydrazone derivatives, stilbene derivatives, silazane derivatives, aromatic dimethylidene compounds, porphyrin compounds, carbodiimide derivatives, diphenylquinone derivatives, tetracarbocyclic compounds, for example naphthaleneperylene, phthalocyanine derivatives, metal complexes of the 8-hydroxyquinoline derivatives, for example Alq₃ (the 8-hydroxyquinoline complexes may also contain triarylaminophenol ligands (US 2007/0134514 A1)), various metal complex-polysilane compounds with metal phthalocyanine, benzoxazole or benzothiazole as ligand, electron-conducting polymers, for example poly(N-vinylcarbazole) (PVK), aniline copolymers, thiophene oligomers, polythiophenes, polythiophene derivatives, polyphenylene derivatives, polyphenylenevinylene derivatives and polyfluorene derivatives.

Particularly preferred low molecular weight matrix materials for triplet emitters are selected from carbazole, ketone, triazine, imidazole, fluorene, spirobifluorene, phenanthrene, dihydrophenanthrene and the isomers and derivatives thereof.

A further preferred material used for the first emitter layer comprises, as well as the emitter(s), an uncharged polymer matrix, for example polystyrene (PS), polymethyimethacrylate (PMMA), polyvinyl butyral (PVB) or polycarbonate (PC).

A preferred material used for the construction of the first emitter layer comprises, as well as the emitter(s), a material having electron-transporting properties (ETM). The ETM may be present either as a repeat unit in the polymer or as a separate compound in the first emitter layer.

In principle, any electron transport material (ETM) known to those skilled in the art may be used as repeat unit in the polymer or as ETM material in the first emitter layer. Suitable ETMs are selected from the group consisting of imidazoles, pyridines, pyrimidines, pyridazines, pyrazines, oxadiazoles, quinolines, quinoxalines, anthracenes, benzanthracenes, pyrenes, perylenes, benzimidazoles, triazines, ketones, phosphine oxides, phenazines, phenanthrolines, triarylboranes and the isomers and derivatives thereof.

Suitable ETM materials are metal chelates of 8-hydroxyquinoline (e.g. Liq, Alq₃, Gaq₃, Mgq₂, Znq₂, Zrq₄), Balq, 4-azaphenanthren-5-ol/Be complexes (U.S. Pat. No. 5,529,853 A; e.g. formula 7), butadiene derivatives (U.S. Pat. No. 4,356,429), heterocyclic optical brighteners (U.S. Pat. No. 4,539,507), benzazoles, for example 1,3,5-tris(2-N-phenylbenzimidazolyl)benzene (TPBI) (U.S. Pat. No. 5,766,779, formula 8), 1,3,5-triazine derivatives (U.S. Pat. No. 6,229,012B1, U.S. Pat. No. 6,225,467B1, DE 10312675 A1, WO 98/04007A1 and U.S. Pat. No. 6,352,791 B1), pyrenes, anthracenes, tetracenes, fluorenes, spirobifluorenes, dendrimers, tetracenes, e.g. rubrene derivatives, 1,10-phenanthroline derivatives (JP 2003/115387, JP 2004/311184, JP 2001/267080, WO 2002/043449), silacylcyclopentadiene derivatives (EP 1480280, EP 1478032, EP 1469533), pyridine derivatives (JP 2004/200162 Kodak), phenanthrolines, e.g. BCP and Bphen, and a number of phenanthrolines bonded via biphenyl or other aromatic groups (US 2007/0252517 A1) or anthracene-bonded phenanthrolines (US 2007/0122656 A1, e.g. formulae 9 and 10), 1,3,4-oxadiazoles, e.g. formula 11, triazoles, e.g. formula 12, triarylboranes, benzimidazole derivatives and other N-heterocyclic compounds (US 2007/0273272 A1), silacyclopentadiene derivatives, borane derivatives, Ga-oxinoid complexes.

A preferred ETM unit is selected from units having a group of the formula C═X in which X may be O, S or Se. Preferably, the ETM unit has the structure of the following formula (34):

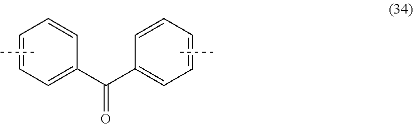

Polymers having such structural units are disclosed, for example, in WO 2004/093207 A2 and WO 2004/013080A1.

Particularly preferred ETM units are fluorene ketones, spirobifluorene ketones or indenofluorene ketones selected from the following formulae (35) to (37):

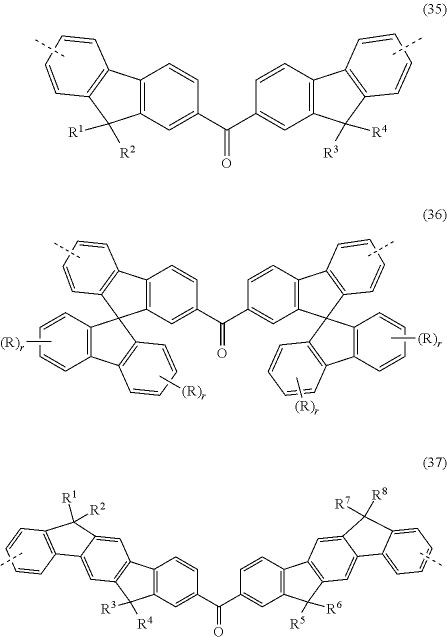

where
R and R¹⁻⁸ are each independently a hydrogen atom, a substituted or unsubstituted aromatic cyclic hydrocarbyl group having 6 to 50 carbon atoms in the ring, a substituted or unsubstituted aromatic heterocyclic group having 5 to 50 ring atoms, a substituted or unsubstituted alkyl group having 1 to 50 carbon atoms, a substituted or unsubstituted cycloalkyl group having 3 to 50 carbon atoms in the ring, a substituted or unsubstituted alkoxy group having 1 to 50 carbon atoms, a substituted or unsubstituted aralkyl group having 6 to 50 carbon atoms in the ring, a substituted or unsubstituted aryloxy group having 5 to 50 carbon atoms in the ring, a substituted or unsubstituted arylthio group having 5 to 50 carbon atoms in the ring, a substituted or unsubstituted alkoxycarbonyl group having 1 to 50 carbon atoms, a substituted or unsubstituted silyl group having 1 to 50 carbon atoms, carboxyl group, a halogen atom, a cyano group, nitro group or hydroxyl group. One or more of the R¹ and R², R³ and R⁴, R⁵ and R⁶, R⁷ and R⁸ pairs optionally form a ring system, and r is 0, 1, 2, 3 or 4.

Further preferred repeat ETM units are selected from the group consisting of imidazole derivatives and benzimidazole derivatives as disclosed, for example, in US 2007/0104977A1. Particular preference is given to units of the following formula (38):

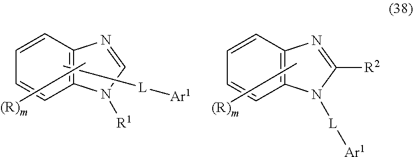

where
R is a hydrogen atom, a C6-60-aryl group which may have a substituent, a pyridyl group which may have a substituent, a quinolyl group which may have a substituent, a C1-20-alkyl group which may have a substituent, or a C1-20-alkoxy group which may have a substituent;
m is an integer from 0 to 4;
R¹ is a C6-60-aryl group which may have a substituent, a pyridyl group which may have a substituent, a quinolyl group which may have a substituent, a C1-20-alkyl group which may have a substituent, or a C1-20-alkoxy group which may have a substituent;
R² is a hydrogen atom, a C6-60-aryl group which may have a substituent, a pyridyl group which may have a substituent, a quinolyl group which may have a substituent, a C1-20-alkyl group which may have a substituent, or a C1-20-alkoxy group which may have a substituent;
L is a C6-60-arylene group which may have a substituent, a pyridinylene group which may have a substituent, a quinolinylene group which may have a substituent, or a fluorenylene group which may have a substituent, and Ar¹ is an C6-60-aryl group which may have a substituent, a pyridinyl group which may have a substituent, or a quinolinyl group which may have a substituent.

Preference is further given to 2,9,10-substituted anthracenes (by 1- or 2-naphthyl and 4- or 3-biphenyl) or molecules containing two anthracene units as disclosed, for example, in US 2008/0193796 A1.

Preference is additionally given to N-heteroaromatic ring systems of the following formulae (39) to (44):

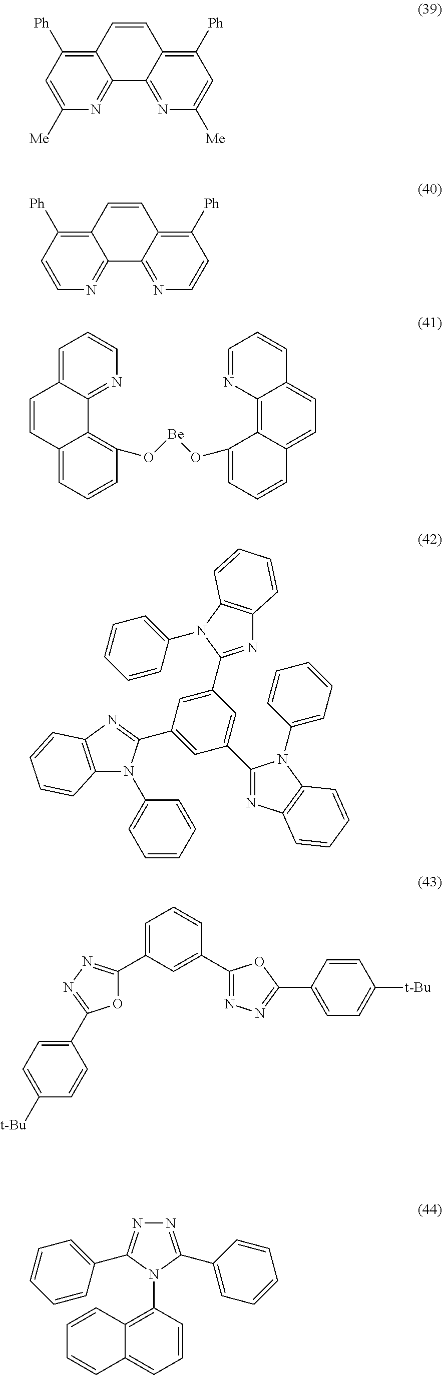

Preference is likewise given to anthracenebenzimidazole derivatives of the following formulae (45) to (47) as disclosed, for example, in U.S. Pat. No. 6,878,469 B2, US 2006/147747 A and EP 1551206 A1:

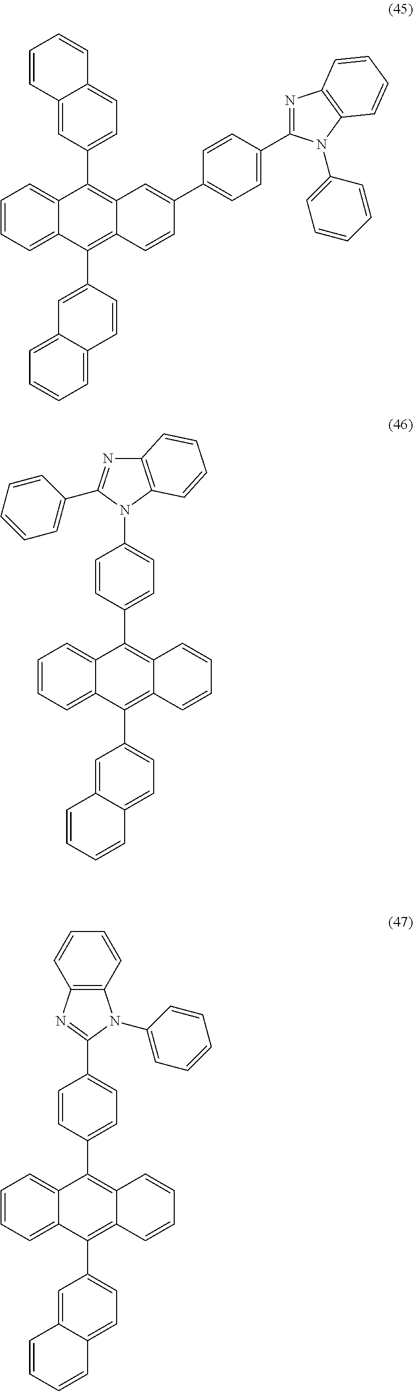 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2nc3ccccc3n2-c2ccc(-c3c4ccccc4c(-c4ccc5ccccc5c4)c4ccccc34)cc2)cc1 ; c1ccc(-n2c(-c3ccc(-c4c5ccccc5c(-c5ccc6ccccc6c5)c5ccccc45)cc3)nc3ccccc32)cc1]

Examples of polymers containing a repeat ETM unit and the synthesis thereof are disclosed, for example, in US 2003/0170490 A1 for triazine as repeat ETM unit.

Preferred structural units having electron-transporting properties for the first emission layer are units which derive from benzophenone, triazine, imidazole, benzimidazole and perylene units, which may optionally be substituted. Particular preference is given to benzophenone, aryltriazine, benzimidazole and diarylperylene units.

Particular preference is given to using repeat ETM units or ETM compounds containing structural units having electron-conducting properties selected from the structural units of the following formulae (48) to (51):

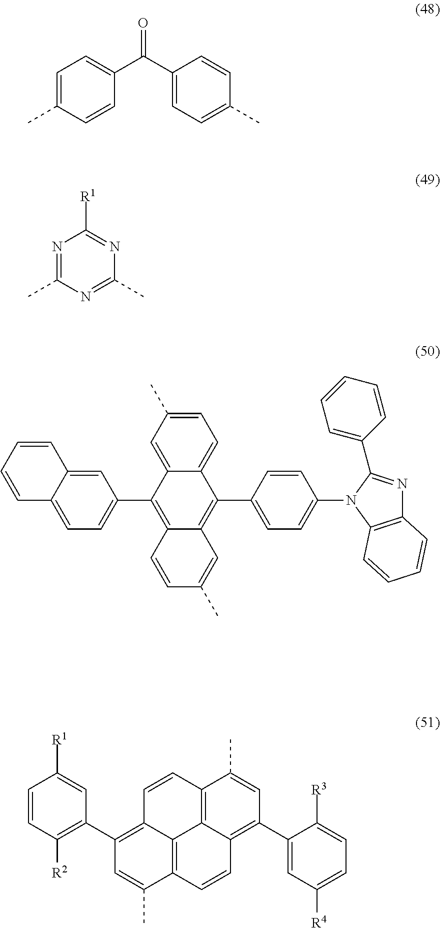

where
R¹ to R⁴ may assume the same definition as for R in formula (36).

The proportion of structural units having electron-conducting properties in the polymer which is used in the first emitter layer is preferably between 001 and 30 mol %, more preferably between 1 and 20 mol % and especially between 10 and 20 mol %.

Preference is given to using, in the first emitter layer, a polymeric matrix material containing one or more different emitters incorporated within the polymer skeleton, or mixtures of polymeric matrix materials, in which case the polymers contain one or more different emitters incorporated within the polymer skeleton.

The emitters in the emitter layers are preferably chosen so as to result in a maximum breadth of emission. Preference is given to combining triplet emitters having the following emissions: green and red; blue and green; bright blue and bright red; blue, green and red. Among these, particular preference is given to using triplet emitters having deep green and deep red emission. Good adjustment of yellow hues in particular is possible using these. Via the variation of the concentration of the individual emitters, it is possible to create and adjust the hues in the desired manner.

Emitters used in the context of the present application can be any molecules which emit from the singlet or triplet state within the visible spectrum. The “visible spectrum” in the context of the present application is understood to mean the wavelength range from 380 nm to 750 nm.

Particular preference is given to electroluminescent devices in which a first emitter has an emission maximum in the green spectral region and a second emitter an emission maximum in the red spectral region.

Further preferred combinations of emitters are those having an emission maximum in the blue and green spectral region, in the bright blue and bright red spectral region, or in the blue, green and red spectral region.

Particular preference is given to electrooptical devices in which at least two triplet emitters are present, having respective emission maxima in the following spectral regions: green and red, blue and green, and bright blue and bright red. In this case, the first triplet emitter is preferably disposed in the first emission layer and the second triplet emitter in the interlayer.

Very particular preference is given to electrooptical devices in which the first triplet emitter has an emission maximum in the green spectral region and the second triplet emitter an emission maximum in the red spectral region.

Very particular preference is likewise given to electrooptical devices in which the first triplet emitter has an emission maximum in the bright blue spectral region and the second triplet emitter an emission maximum in the yellow spectral region.

Very particular preference is further given to electrooptical devices in which at least one singlet emitter is present, having an emission maximum in the green, red or blue spectral region.

In general, the emitters are present in the emitter layers in a dopant-matrix system. The concentration of the emitter(s) is preferably in the range from 0.01 to 30 mol %, more preferably in the range from 1 to 25 mol % and especially in the range from 2 to 20 mol %.

More preferably, the first emitter layer comprises electron-transporting substances.

In a further preferred embodiment, the electrooptical device of the invention comprises, in the first emitter layer and/or in the second emitter layer, substances which promote the transfer of excitation energy to the triplet state. These are, for example, carbazoles, ketones, phosphine oxides, silanes, sulfoxides, compounds having heavy metal atoms, bromine compounds or phosphorescence sensitizers.

In a preferred embodiment, the organic semiconductor in the first emitter layer is a semiconductive polymer, preferably a semiconductive copolymer.

The organic semiconductive polymer preferably has repeat units which derive from fluorene, spirobifluorene, indenofluorene, phenanthrene, dihydrophenanthrene, phenylene, dibenzothiophene, dibenzofuran, phenylenevinylene and derivatives thereof, where these repeat units may be substituted.

Preferred semiconductive copolymers used in the first emitter layer have further repeat units which derive from triarylamines, preferably from those having repeat units of the following formulae (52) to (54):

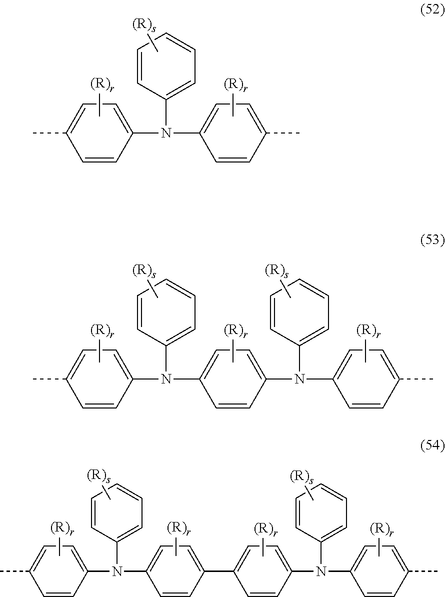

where
R, which may be the same or different at each instance, is selected from H, substituted or unsubstituted aromatic or heteroaromatic group, alkyl group, cycloalkyl group, alkoxy group, aralkyl group, aryloxy group, arylthio group, alkoxycarbonyl group, silyl group, carboxyl group, halogen atom, cyano group, nitro group and hydroxyl group,
r is 0, 1, 2, 3 or 4 and
s is 0, 1, 2, 3, 4 or 5.

The electrooptical devices of the invention more preferably have a very simple structure. In the extreme case, the device may be one comprising, as well as a cathode layer and anode layer, only two or more emitter layers disposed in between.

A preferred embodiment of the electrooptical device of the invention comprises at least one additional electron injection layer disposed directly between the first emission layer and the cathode.

Preferably, the electrooptical device of the invention is applied to a substrate, preferably to a transparent substrate. Applied in turn thereto is preferably an electrode made from transparent or semitransparent material, preferably made from indium tin oxide (ITO).

In a further preferred embodiment, the electrooptical device of the invention has a third emission layer. This third emission layer preferably comprises at least one low molecular weight emitter which may be selected from the above-described groups of emitters, and also at least one low molecular weight matrix material which may be selected from the above-described matrix materials. Preferably, the first and second emission layers are processed from solution, and the third emission layer is applied by vapor deposition under reduced pressure. In a particularly preferred embodiment, the first, second and third emission layers emit red, green and blue light, with adjustment of the light intensity of the individual layers so as to result in white emission overall.

More preferably, the electrooptical device of the invention consists solely of anode, buffer layer, for example comprising PANI or PEDOT, hole injection layer, two emitter layers, hole blocker layer, electron transport layer and cathode, optionally constructed on a transparent substrate.

More preferably, the electrooptical device further comprises a hole injection layer positioned between anode and interlayer composed of hole-conducting polymer, preferably a layer composed of poly(ethylenedioxythiophene) (PEDOT).

The electrooptical devices of the invention preferably have thicknesses of the mutually delimited individual layers in the range from 1 to 150 nm, more preferably in the range from 3 to 100 nm and especially in the range from 5 to 80 nm.

Preferred electrooptical devices of the invention comprise polymeric materials having glass transition temperatures T₉ of greater than 90° C., more preferably of greater than 100° C. and especially of greater than 120° C.

It is particularly preferable when all the polymers used in the device of the invention have the high glass transition temperatures described.

Cathode materials used in the electrooptical devices of the invention may be materials known per se. Especially for OLEDs, materials having a low work function are used. Examples of these are metals, metal combinations or metal alloys having a low work function, for example Ca, Sr, Ba, Cs, Mg, Al, In and Mg/Ag.

The construction of the devices of the invention can be achieved by various production methods.

Firstly, it is possible to apply at least some of the layers under reduced pressure. Some of the layers, especially the emitter layers, are applied from solution. It is also possible without exercising inventive skill to apply all the layers from solution.

In the case of application under reduced pressure, structuring is accomplished using shadowmasks, while a wide variety of different printing processes are employable from solution.

Printing methods in the context of the present application also include those which proceed from the solid state, such as thermal transfer or LITI.

In the case of the solvent-based methods, solvents which dissolve the substances used are used. The type of substance is not crucial to the present invention.

The electrooptical device of the invention can thus be produced by methods known per se, with application at least of the two emitter layers from solution, preferably by printing methods, more preferably by inkjet printing.

In a preferred embodiment, the electrooptical device is an organic light-emitting device (organic light-emitting diode (OLED)).

In a further preferred embodiment, the electrooptical device is an organic light-emitting electrochemical cell (OLEC). The OLEC has two electrodes, at least one emission layer and an interlayer between the emission layer and an electrode, as described above, the emission layer including at least one ionic compound. The principle of the OLEC is described in Gibing Pei et al., Science, 1995, 269, 1086-1088.

The electrooptical device of the invention can be used in various applications. Particular preference is given to using the electrooptical devices of the invention in displays, as backlighting and as lighting. A further preferred field of use of the electrooptical devices of the invention relates to use in the cosmetic and therapeutic sector, as disclosed, for example, in EP 1444008 and GB 2408092.

These uses likewise form part of the subject matter of the present application.

The examples which follow elucidate the invention without restricting it.

### WORKING EXAMPLES

Interlayer materials of the invention that may be used may be any hole-dominated polymers which additionally contain an emitter having a LUMO below the lowest LUMO of the other interlayer components and the preceding layer. The use of interlayers in organic light-emitting diodes is disclosed, for example, in WO 2004/084260. Typical interlayer polymers are disclosed in WO 2004/041901, but it is possible to convert virtually any conjugated or semi-conjugated polymers used in PLEDs to interlayer polymers by the incorporation of large proportions of hole-conducting units (typically triarylamines). Any of these interlayers can be converted to an interlayer of the invention by the incorporation of emitters which can be incorporated by polymerization or doping.

### Examples 1 to 10

### Polymer Examples

The polymers P1 to P10 of the invention are synthesized using the following monomers (percentages=mol %) by SUZUKI coupling in accordance with WO 03/048225 A2:

### Example 1

### Polymer P1

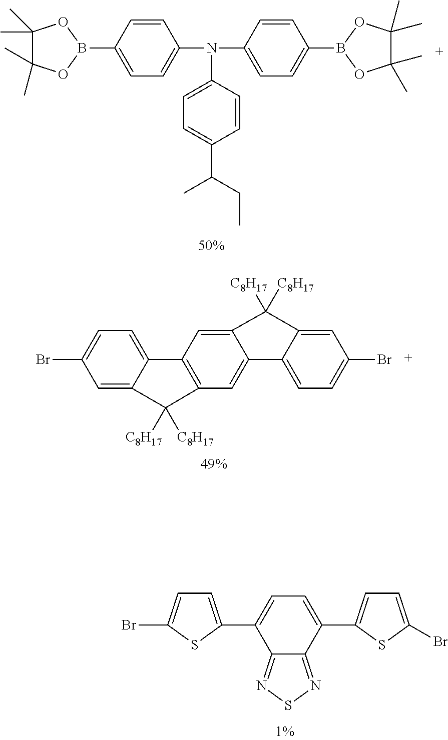

### Example 2

### Polymer P2

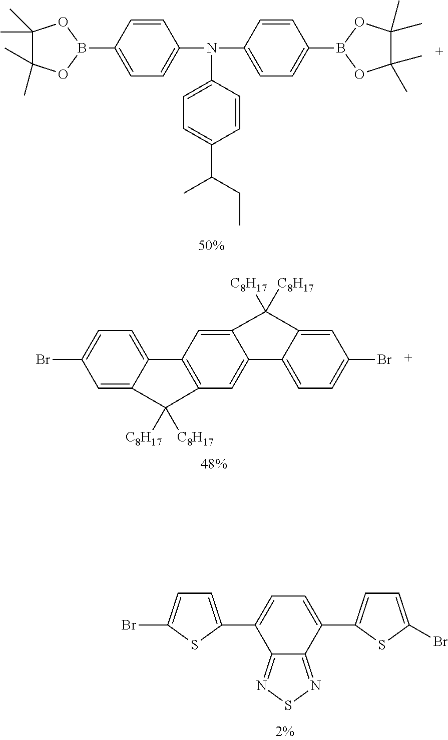

### Example 3

### Polymer P3

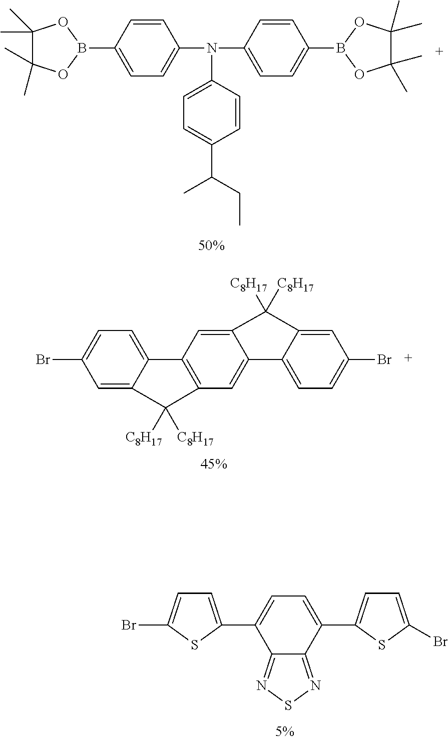

### Example 4

### Polymer P4

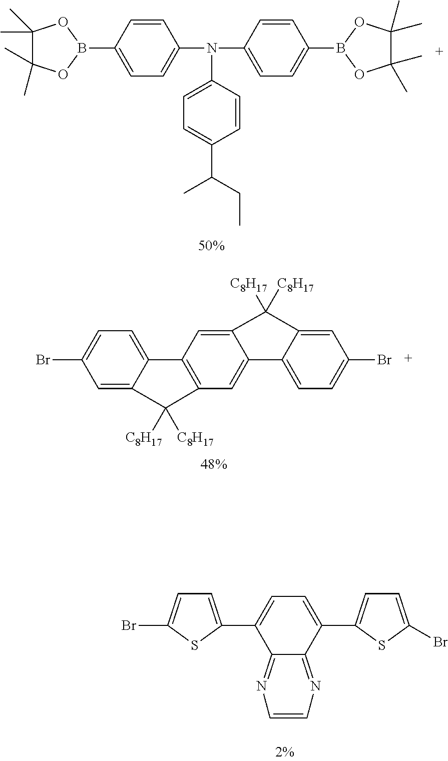

### Example 5

### Polymer P5

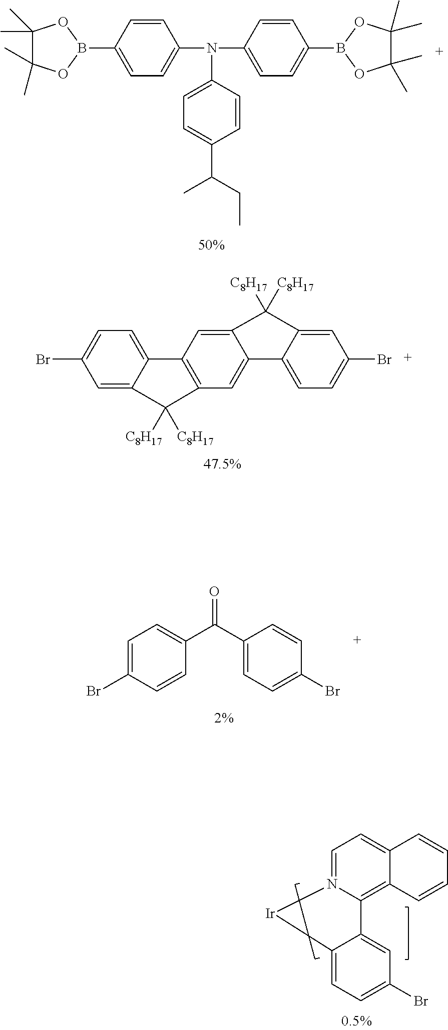

### Example 6

### Polymer P6

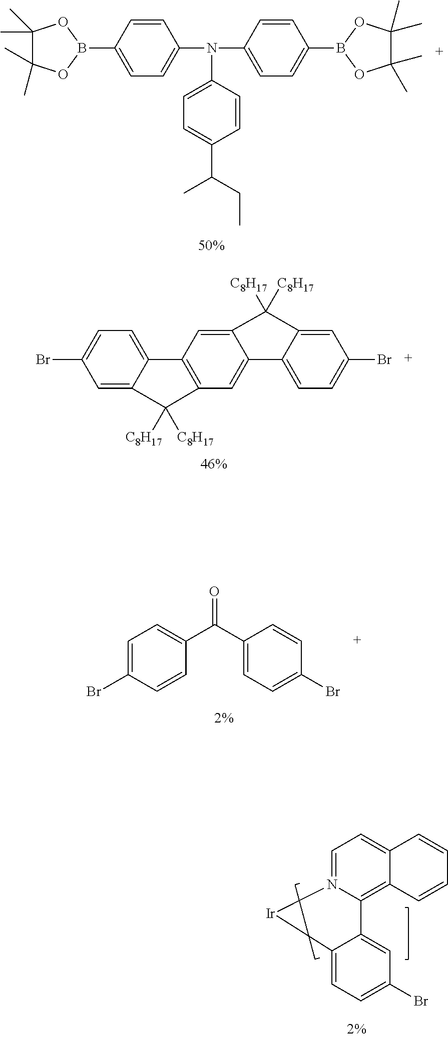

### Example 7

### Polymer P7

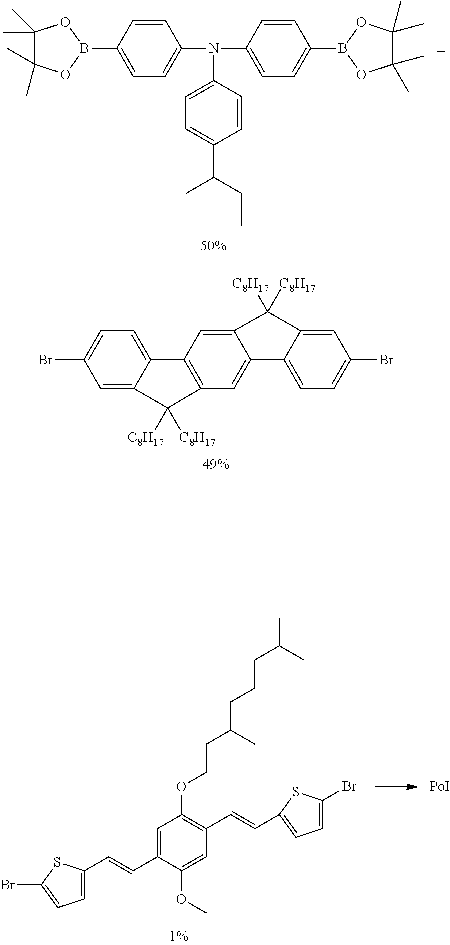

### Example 8

### Polymer P8

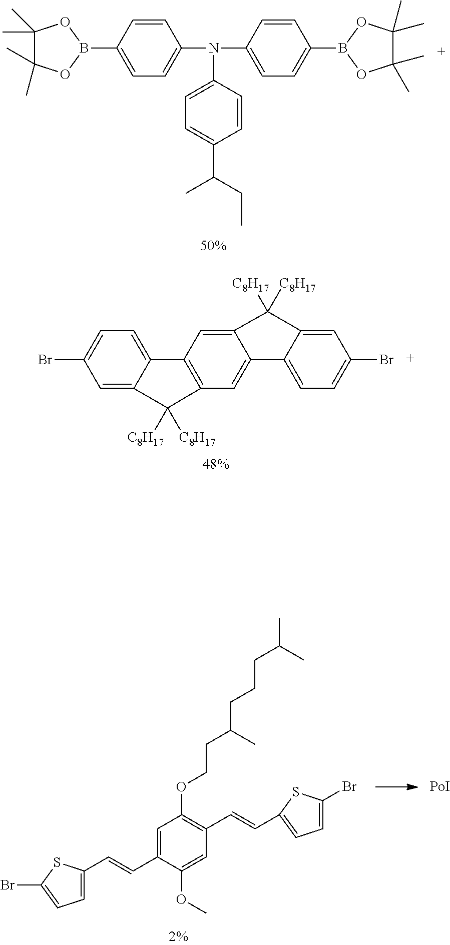

### Example 9

### Polymer P9

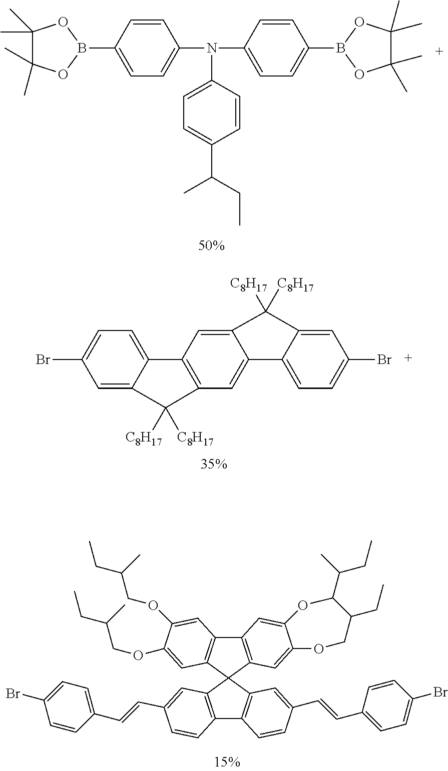

### Example 10

### Polymer P10

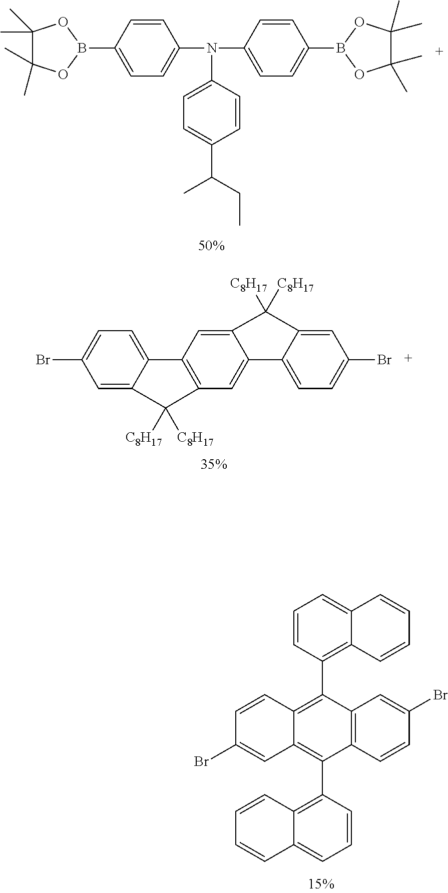

### Example 11 to 27

### Device Examples

### Production of PLEDs and Solution-Processed Small Molecule Devices

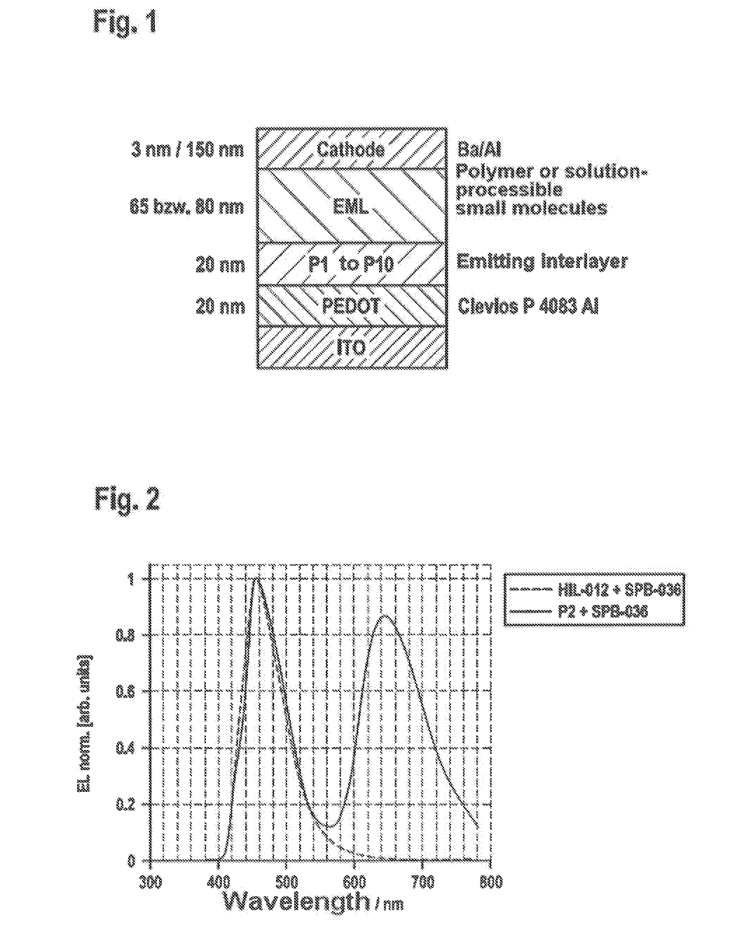

There have already been many descriptions of the production of polymeric organic light-emitting diodes (PLEDs) in the literature (for example in WO 2004/037887 A2). In order to illustrate the present invention by way of example, PLEDs having polymers P1 to P10 as what is called the interlayer are produced by spin-coating. Any other production method from solution (inkjet printing, offset printing, screen printing, airbrushing, etc.) and the vapor deposition of the active layers onto the solution-processed interlayer, however, likewise leads to components of the invention. A typical device for the examples described here has the structure shown in FIG. 1.

For this purpose, specially manufactured substrates from Technoprint are used in a layout specially designed for this purpose. The ITO structure (indium tin oxide, a transparent conductive anode) was applied to soda-lime glass by sputtering in such a pattern that the cathode applied by vapor deposition at the end of the production process results in 4 pixels of 2×2 mm.

The substrates are cleaned in a cleanroom with DI water and a detergent (Deconex 15 PF) and then activated by a UV/ozone plasma treatment. Thereafter, likewise in the cleanroom, an 80 nm layer of PEDOT (PEDOT is a polythiophene derivative (Clevios P 4083 A1) from H. C. Starck, Goslar, which is supplied as an aqueous dispersion) is applied by spin-coating. The required spin rate depends on the degree of dilution and the specific spin-coater geometry (typical value for 80 nm: 4500 rpm). In order to remove residual water from the layer, the substrates are baked on a hotplate at 180° C. for 10 minutes. Thereafter, 20 nm of an interlayer are first spun on under an inert gas atmosphere (nitrogen or argon). In the present case, this comprises polymers P1 to P10, which are processed at a concentration of 5 g/L from toluene. All interlayers in these device examples are baked at 180° C. under inert gas for 1 hour. Subsequently, 65 nm of the polymer layers are applied from toluene solutions (typical concentrations 8 to 12 g/L). It is also possible to use solution-processible small molecules in an analogous manner, but these then have to be made up in higher concentration because of the low viscosity of the solutions. Typical concentrations here are 20 to 28 mg/mL. It has also been found to be advantageous to use a layer thickness of 80 nm here. In the present examples, this second solution-processed layer too, the main emission layer (“EML”), is applied by spin-coating and then baked under inert gas, specifically at 180° C. for 10 minutes. Thereafter, the Ba/Al cathode is applied by vapor deposition in the pattern specified through a vapor deposition mask (high-purity metals from Aldrich, particularly barium 99.99% (cat. no. 474711); vapor deposition systems from Lesker or the like, typical vacuum level 5×10⁻⁶ mbar). In order to protect the cathode in particular from air and air humidity, the device is finally encapsulated. The device is encapsulated by bonding a commercially available glass cover over the pixelated area. Subsequently, the device is characterized.

For this purpose, the devices are clamped into holders manufactured specially for the substrate size and contact-connected by means of spring contacts. A photodiode with an eye response filter can be placed directly onto the analysis holder, in order to rule out any influences by outside light.

Typically, the voltages are increased from 0 to max. 20 V in 0.2 V steps and lowered again. For each measurement point, the current through the device and the photocurrent obtained are measured by the photodiode. In this manner, the IUL data of the test devices are obtained. Important characteristic parameters are the maximum efficiency measured (“Max. eff” in cd/A) and the voltage required for 100 cd/m².

In order also to find the color and the exact electroluminescence spectrum of the test devices, the first measurement is followed by application of the voltage required for 100 cd/m² once again and replacement of the photodiode with a spectrum measurement head. The latter is connected by an optical fiber to a spectrometer (Ocean Optics). The spectrum measured can be used to derive the color coordinates (CIE: Commission International de I′éclairage, standard observer from 1931).

A factor of particular significance for the usability of the materials is the lifetime of the devices. This is measured in a test setup very similar to the first evaluation, in such a way that a starting luminance is set (e.g. 1000 cd/m²). The current required for this luminance is kept constant, while the voltage typically rises and the luminance decreases. The lifetime has been attained when the starting luminance has dropped to 50% of the starting value, which is why this value is also referred to as LT₅₀. If an extrapolation factor has been determined, the lifetime can also be measured in an accelerated manner by setting a higher starting luminance. In this case, the measurement apparatus keeps the current constant, and so it shows the electrical degradation of the components in a voltage rise.

### Example 11

A first unoptimized two-color white with cold white color coordinates is established by the combination of the interlayer P2 with the blue polymer SPB-036 from Merck. The electroluminescence spectrum of the blue polymer on a “colorless” interlayer (HIL-012 from Merck) and the spectrum of the device of the invention are shown in FIG. 2. The results of the optoelectronic characterization of the component are summarized in table 1.

TABLE 1

| | | | Max. | | | |
|---|---|---|---|---|---|---|
| Exam- | | | eff. | U_{(100 cd/m}^{²}₎ | CIE | LT₅₀ |
| ple | IL | EML | [cd/A] | [V] | [x/y] | [h @ cd/m²] |
| 11 | P2 | SPB-036 | 3.6 | 7.4 | 0.31/0.28 | 145 @ 1000 |

### Example 12 to 14

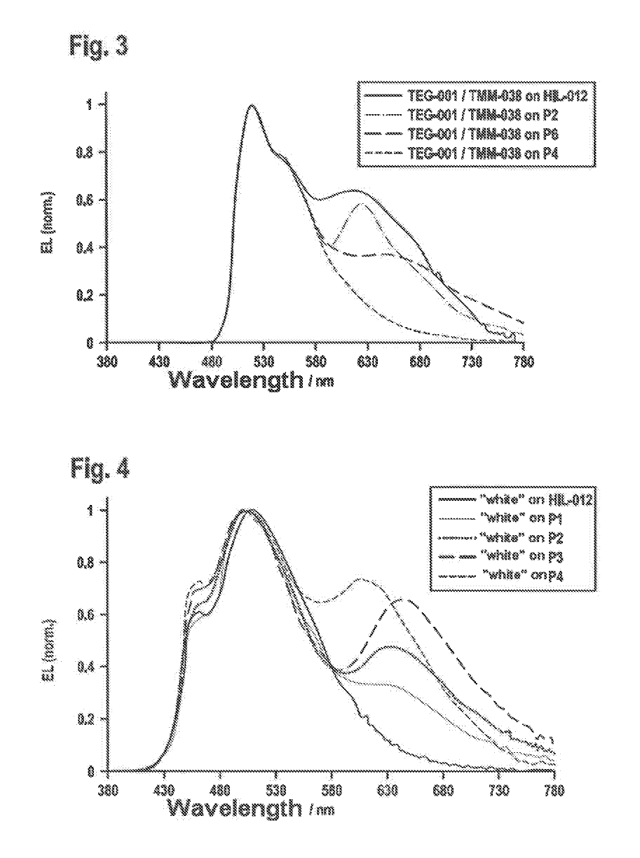

As a precursor for a three-color white, it is possible to achieve a yellow color impression by combination of a red interlayer with a solution-processed green EML. This is accomplished in (unoptimized) examples 12 to 14 by using the interlayers P2, P4 and P6 in combination with a triplet green (TEG-001 in TMM-038 from Merck). FIG. 3 shows the spectrum of the pure triplet green on HIL-012 and the spectra of the components of the invention comprising P2, P4 and P6.

TABLE 2

| | | | Max. | | | LT₅₀ |
|---|---|---|---|---|---|---|
| Exam- | | | eff. | U_{(100 cd/m}^{²}₎ | CIE | [h @ |
| ple | IL | EML | [cd/A] | [V] | [x/y] | cd/m²] |
| 12 | P2 | T green | 18 | 5.0 | 0.39/0.58 | 1500 @ |
| | | | | | | 1000 |
| 13 | P4 | T green | 19 | 4.3 | 0.40/0.56 | 4000 @ |
| | | | | | | 1000 |
| 14 | P6 | T green | 21.5 | 4.3 | 0.41/0.56 | 1800 @ |
| | | | | | | 1000 |

### Example 15 to 18

White components for lighting applications can also be improved with the aid of the self-emitting interlayer. Thus, color tuning to ever redder white light is possible, in order to take account, for example, of cultural differences. Examples 15 to 18 show the results for solution-processed OLEDs in the structure of FIG. 1 in which a white polymer which is synthesized without a red emitter is used as EML (SPW-110 from Merck; prepared without the red unit normally incorporated in the polymer). By exchange of the interlayers, it is possible here to vary color coordinates without re-synthesizing the EML polymer. FIG. 4 again shows the EL spectrum of the device comprising HIL-012 from Merck and the spectra with the interlayer polymers P1 to P4 of the invention.

TABLE 3

| | | | Max. | | | LT₅₀ |
|---|---|---|---|---|---|---|
| Exam- | | | eff. | U_{(100 cd/m}^{²}₎ | CIE | [h @ |
| ple | IL | EML | [cd/A] | [V] | [x/y] | cd/m² |
| 15 | P1 | “white” | 9.3 | 6.0 | 0.28/0.42 | 1920 @ |
| | | | | | | 1000 |
| 16 | P2 | “white” | 7.4 | 6.4 | 0.30/0.40 | 1720 @ |
| | | | | | | 1000 |
| 17 | P3 | “white” | 4.7 | 7.2 | 0.31/0.38 | 1250 @ |
| | | | | | | 1000 |
| 18 | P4 | “white” | 9.4 | 6.1 | 0.31/0.36 | 2200 @ |
| | | | | | | 1000 |

### Example 19 to 20

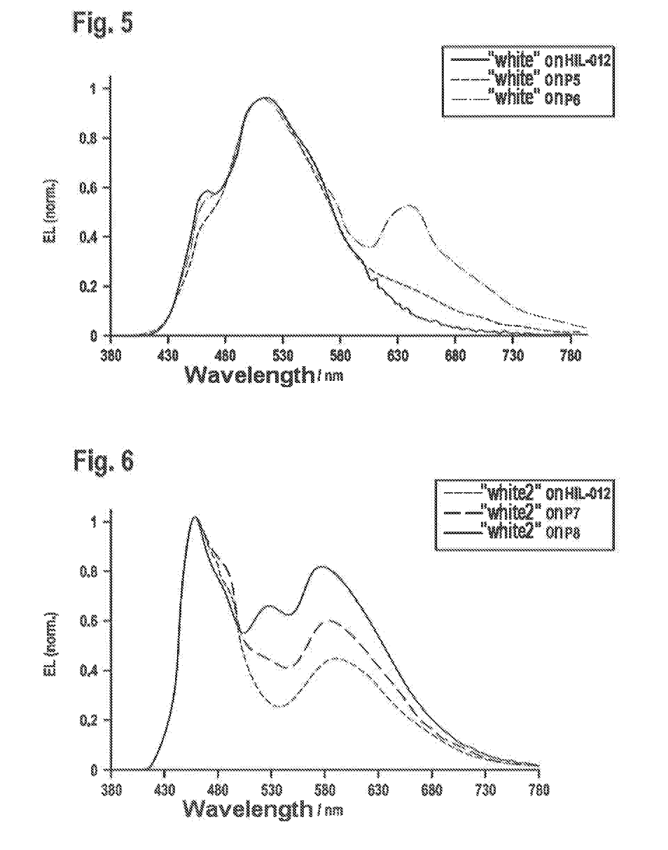

The interlayer polymers P5 and P6 are also used to conduct the same experiment as in examples 15 to 18. The spectra are shown in FIG. 5, and the characteristics of the devices in table 4. Again, it is possible to adjust the red component in the device.

TABLE 4

| | | | Max. | | | LT₅₀ |
|---|---|---|---|---|---|---|
| Exam- | | | eff. | U_{(100 cd/m}^{²}₎ | CIE | [h @ |
| ple | IL | EML | [cd/A] | [V] | [x/y] | cd/m²] |
| 19 | P5 | “white” | 11.1 | 57 | 0.27/0.45 | 1500 @ |
| | | | | | | 1000 |
| 20 | P6 | “white” | 10.9 | 5.5 | 0.31/0.42 | 1700 @ |
| | | | | | | 1000 |

### Examples 21 to 23

In order to confirm that the interlayers of the invention need not necessarily constitute the red component in the device spectrum, the polymers P7 and P8 comprising a green emitter are synthesized. OLEDs of the invention are produced here by using a “white” polymer not comprising any green emitter (SPW-106 from Merck without the green unit normally present therein). The results of the optoelectronic characterization are shown in table 5, and the electroluminescence spectra of the OLEDs in FIG. 6. In this case, the green interlayer has the additional advantage of also amplifying the red component in the spectrum, since the energy transfer from blue to green does not work without incorporated green.

TABLE 5

| | | | Max. | | | LT₅₀ |
|---|---|---|---|---|---|---|
| Exam- | | | eff. | U_{(100 cd/m}^{²}₎ | CIE | [h @ |
| ple | IL | EML | [cd/A] | [V] | [x/y] | cd/m²] |
| 21 | HIL- | “white2” | 6.6 | 6.5 | 0.28/0.26 | 700 @ |
| | 012 | | | | | 1000 |
| 22 | P7 | “white2” | 7.5 | 6.9 | 0.31/0.32 | 1750 @ |
| | | | | | | 1000 |
| 23 | P8 | “white2” | 7.5 | 6.7 | 0.31/0.35 | 1600 @ |
| | | | | | | 1000 |

### Example 24 to 26

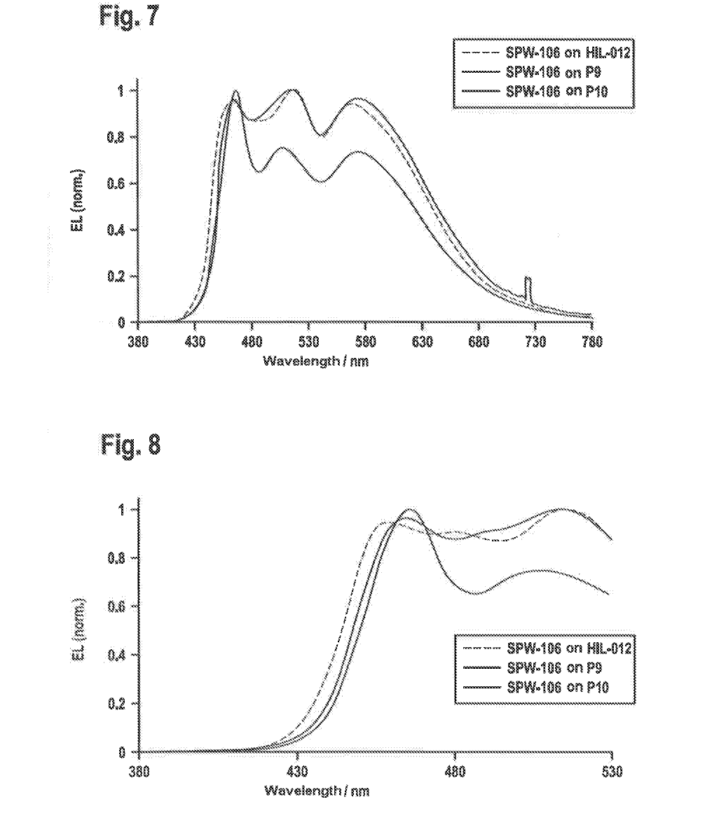

Showing the suitability of the blue interlayers P9 and P10 is more difficult since the prerequisite of a low LUMO is more difficult to satisfy compared to the EMLs used. Examples 24 to 26 therefore show the results of OLEDs comprising the white Merck polymer SPW-106 which is processed on the colorless interlayer HIL-012 for comparison, and on the interlayers P9 and P10. FIGS. 7 and 8 show the EL spectra. Particularly in the enlargement, it can be seen that the deeper blue emitter in the interlayers is responsible for the blue emission. Thus, it is also possible to obtain blue emission from the interlayer.

TABLE 6

| | | | Max. | | | LT₅₀ |
|---|---|---|---|---|---|---|
| Exam- | | | eff. | U_{(100 cd/m}^{²}₎ | CIE | [h @ |
| ple | IL | EML | [cd/A] | [V] | [x/y] | cd/m²] |
| 24 | HIL- | SPW-106 | 8.2 | 6.7 | 0.31/0.37 | 2000 @ |
| | 012 | | | | | 1000 |
| 25 | P9 | SPW-106 | 9.0 | 6.4 | 0.32/0.39 | 1500 @ |
| | | | | | | 1000 |
| 26 | P10 | SPIN-106 | 8.2 | 6.7 | 0.31/037 | 1500 @ |
| | | | | | | 1000 |

### Example 27

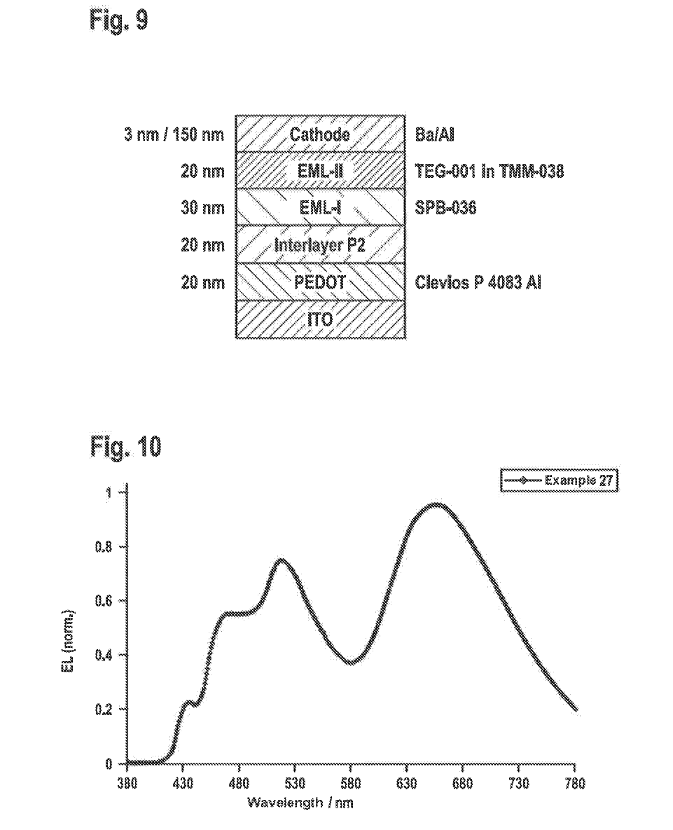

Emitting interlayer polymers are particularly useful in devices which are to emit white light. In this example, interlayer P2 is coated as usual, a blue EML polymer (SPB-036 as in example 11) is processed thereon, and a green triplet EML is applied by vapor deposition (TEG-001 in TMM-038). The device structure is shown in FIG. 9. The white EL spectrum containing all the color components is shown in FIG. 10. The quantum efficiency of the device is 10% EQE, even though singlet components for the most part have been used. The color coordinates show a virtually ideal white with CIE (x/y)=0.37/0.38.

Since TEG-001 is solution-processible in TMM-038, it is possible by using a crosslinked blue polymer to produce a solution-processed multilayer white. Conversely, the green EML-II used here can be replaced by other vapor-deposited green triplet layers and additional layers can be introduced between EML-II and the cathode.

### Summary of the Results:

The use of the interlayer polymers of the invention in OLED devices leads to elegant options for adjustment of color coordinates, to a distinct increase in device flexibility, to combinatorial options with vapor-deposited layers, and particularly to multicolor devices with good efficiencies and lifetimes. Thus, the devices are a great advance over the prior art particularly for lighting applications.

1-20. (canceled)

21. An electro-optical device comprising:
a) an anode;
b) a cathode; and
c) at least one first emitter layer disposed between the anode and the cathode, comprising at least one semiconductive organic material,
wherein at least one second emitter layer disposed between the first emitter layer and the anode includes at least one polymer having hole-conducting properties and at least one emitter.

22. The electro-optical device of claim 21, wherein the at least one emitter of the second emitter layer has a LUMO higher than the LUMO of the semiconductive organic material of the first emitter layer.

23. The electro-optical device of claim 22, wherein the LUMO of the at least one emitter of the second emitter layer is at least 0.1 eV higher than the LUMO of the semiconductive organic material of the first emitter layer.

24. The electro-optical device of claim 23, wherein the LUMO of the at least one emitter of the second emitter layer is at least 0.2 eV higher than the LUMO of the semiconductive organic material of the first emitter layer.

25. The electro-optical device of claim 21, wherein the at least one emitter of the second emitter layer is a repeat unit of the polymer having hole-conducting properties.

26. The electro-optical device of claim 25, wherein the proportion of the emitter structural units in the hole-conducting polymer of the second emitter layer is in the range of from 0.01 to 20 mol %.

27. The electro-optical device of claim 21, wherein the polymer having hole-conducting properties comprises triarylamine units as repeat units.

28. The electro-optical device of claim 27, wherein the triarylamine units are selected from the group consisting of the structural units of formulae (18) to (20): 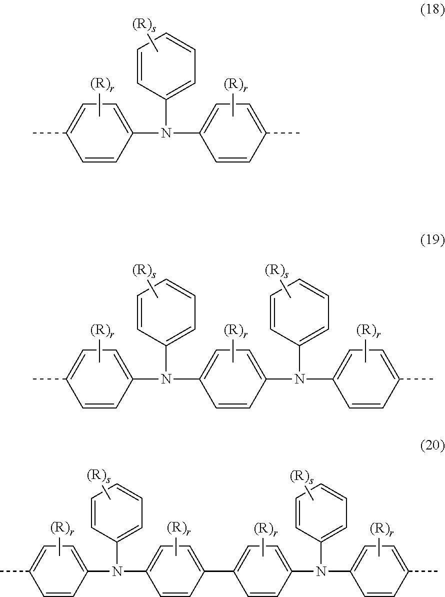
wherein
R may be the same or different at each instance and is selected from the group consisting of H, substituted or unsubstituted aromatic or heteroaromatic groups, alkyl groups, cycloalkyl groups, alkoxy groups, aralkyl groups, aryloxy groups, arylthio groups, alkoxycarbonyl groups, silyl groups, carboxyl groups, halogen atoms, cyano groups, nitro groups, and hydroxyl groups;
r is 0, 1, 2, 3, or 4; and
s is 0, 1, 2, 3, 4, or 5.

29. The electro-optical device of claim 21, wherein the polymer having hole-conducting properties comprises, as repeat units, fluorene, spirobifluorene, indenofluorene, phenanthrene, dihydrophenanthrene, dibenzofuran, and/or dibenzothiophene units, each of which are optionally unsubstituted or substituted.

30. The electro-optical device of claim 21, wherein the semiconductive organic material of the first emitter layer is a semiconductive polymer.

31. The electro-optical device of claim 30, wherein the semiconductive polymer is a semiconductive conjugated copolymer.

32. The electro-optical device of claim 31, wherein the semiconductive conjugated copolymer comprises, as repeat units, fluorene, spirobifluorene, indenofluorene, phenanthrene, dihydrophenanthrene, dibenzofuran, and/or dibenzothiophene units, each of which are optionally unsubstituted or substituted.

33. The electro-optical device of claim 31, wherein the semiconductive conjugated copolymer comprises triarylamines as repeat units.

34. The electro-optical device of claim 33, wherein the triarylamine units are selected from the group consisting of the structural units of formulae (18) to (20): 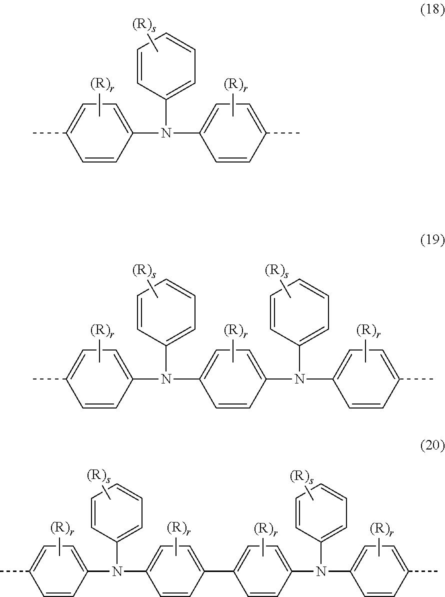
wherein
R may be the same or different at each instance and is selected from the group consisting of H, substituted or unsubstituted aromatic or heteroaromatic groups, alkyl groups, cycloalkyl groups, alkoxy groups, aralkyl groups, aryloxy groups, arylthio groups, alkoxycarbonyl groups, silyl groups, carboxyl groups, halogen atoms, cyano groups, nitro groups, and hydroxy groups;
r is 0, 1, 2, 3, or 4; and
s is 0, 1, 2, 3, 4, or 5

35. The electro-optical device of claim 21, wherein the first emitter layer comprises a polymeric matrix material comprising at least one emitter incorporated within the polymer, in that the first emitter layer comprises at least one polymeric matrix material and at least one emitter, or in that the first emitter layer comprises at least one low molecular weight matrix material and at least one emitter.

36. The electro-optical device of claim 21, wherein at least two triplet emitters are present, having respective emission maxima in the green and red, blue and green or bright blue and bright red spectral regions.

37. The electro-optical device of claim 36, wherein one triplet emitter is disposed in the first emitter layer and the second triplet emitter is disposed in the second emitter layer.

38. The electro-optical device of claim 36, wherein the first triplet emitter has an emission maximum in the green spectral region and the second triplet emitter an emission maximum in the red spectral region.

39. The electro-optical device of claim 21, wherein at least one singlet emitter having an emission maximum in the green, red, or blue spectral region is present.

40. The electro-optical device of claim 21, further comprising a hole injection layer disposed between anode and the second emitter layer.

41. The electro-optical device of claim 40, wherein the hole injection layer is composed of poly(ethylenedioxythiophene).

42. The electro-optical device of claim 21, wherein the electro-optical device consists of an anode, a hole injection layer, a second emitter layer, preferably having two emitters, a first emitter layer, an electron transport layer, and a cathode, optionally disposed on a transparent substrate.

43. The electro-optical device of claim 42, wherein the second emitter layer comprises two emitters.

44. The electro-optical device of claim 21, wherein the electro-optical device is an organic light-emitting diode or an organic light-emitting electrochemical cell.
